(19) United States
(12) Patent Application Publication
(10) Pub. No.: US 2026/0088210 A1
(43) Pub. Date: Mar. 26, 2026

(54) MULTILAYER SUBSTRATE

(71) Applicant: Mitsubishi Electric Corporation, Tokyo (JP)

(72) Inventor: Yuta SUGIYAMA, Tokyo (JP)

(73) Assignee: Mitsubishi Electric Corporation, Tokyo (JP)

(21) Appl. No.: 19/388,163

(22) Filed: Nov. 13, 2025

Related U.S. Application Data
(63) Continuation of application No. PCT/JP2023/025214, filed on Jul. 7, 2023.

(51) Int. Cl. H01F 27/28; H01P 3/08; H01P 7/06

(52) U.S. Cl. CPC H01F 27/2804; H01P 3/08; H01P 7/065; H01F 2027/2809

(57) ABSTRACT

A multilayer substrate includes: a substrate body formed of resin or ceramic; a hollow portion provided inside the substrate body; a magnet provided inside the hollow portion; and a coil provided around the hollow portion in the substrate body.

### CROSS REFERENCE TO RELATED APPLICATION

This application is a Continuation of PCT International Application No. PCT/JP2023/025214, filed on Jul. 7, 2023, which is hereby expressly incorporated by reference into the present application.

### TECHNICAL FIELD

The present disclosure relates to a multilayer substrate incorporating a movable unit.

### BACKGROUND ART

Patent Literature 1 discloses a technique in which a multilayer substrate has a hollow structure and an electronic component is mounted in a hollow portion thereof.

### CITATION LIST

### Patent Literature

Patent Literature 1: JP 2004-179573 A

### SUMMARY OF INVENTION

### Technical Problem

In the multilayer substrate disclosed in Patent Literature 1, an electronic component is mounted in the hollow portion, and the electronic component is not moved in the hollow portion.

The present disclosure has been made to solve the above problem, and an object thereof is to provide a multilayer substrate in which it is possible to move a movable unit inside a hollow portion.

### Solution to Problem

A multilayer substrate according to the present disclosure includes: a substrate body formed of resin or ceramic; a hollow portion provided inside the substrate body; a movable body provided inside the hollow portion and formed of a conductor or a magnetic body; a coil provided around the hollow portion in the substrate body; a protrusion provided on a lower surface of the movable body and formed of a conductive material; a waveguide provided on the substrate body; and a cavity resonator provided in a middle portion of the waveguide and into and out of which the protrusion is inserted and pulled.

### Advantageous Effects of Invention

According to the present disclosure, a movable body can be moved inside a hollow portion. In this case, the present disclosure makes it possible to produce the hollow portion without using a semiconductor manufacturing technique and micro electro mechanical systems (MEMS) technology.

### BRIEF DESCRIPTION OF DRAWINGS

FIGS. 1A and 1B are longitudinal cross-sectional views of a multilayer substrate according to a first embodiment. FIG. 1A is a cross-sectional view illustrating a state (non-conductive state) in which a magnet has moved downward in a hollow portion. FIG. 1B is a cross-sectional view illustrating a state (conductive state) in which the magnet has moved upward in the hollow portion.

FIGS. 2A to 2C are transverse cross-sectional views of the multilayer substrate according to the first embodiment. FIG. 2A is a cross-sectional view taken along line A-A in FIG. 1A. FIG. 2B is a cross-sectional view taken along line B-B in FIG. 1A.

FIG. 2C is a cross-sectional view taken along line C-C in FIG. 1A.

FIGS. 3A and 3B are cross-sectional views illustrating a configuration of Modification 1 of the multilayer substrate according to the first embodiment. FIG. 3A is a longitudinal cross-sectional view of Modification 1. FIG. 3B is a cross-sectional view taken along line D-D in FIG. 3.

FIGS. 4A and 4B are cross-sectional views illustrating configurations of Modifications 2 and 3 of the multilayer substrate according to the first embodiment.

FIG. 4A is a longitudinal cross-sectional view of Modification 2. FIG. 4B is a longitudinal cross-sectional view of Modification 3.

FIGS. 5A and 5B are cross-sectional views illustrating configurations of Modifications 4 and 5 of the multilayer substrate according to the first embodiment.

FIG. 5A is a longitudinal cross-sectional view of Modification 4. FIG. 5B is a longitudinal cross-sectional view of Modification 5.

FIG. 6 is a longitudinal cross-sectional view of Modification 6 of the multilayer substrate according to the first embodiment.

FIGS. 7A and 7B are longitudinal cross-sectional views of a multilayer substrate according to a second embodiment. FIG. 7A is a cross-sectional view illustrating a state in which a magnet has moved upward in a hollow portion. FIG. 7B is a cross-sectional view illustrating a state in which the magnet has moved downward in the hollow portion.

FIGS. 8A and 8B are cross-sectional views illustrating a configuration of Modifications 1 and 2 of the multilayer substrate according to the second embodiment. FIG. 8A is a longitudinal cross-sectional view of Modification 1. FIG. 8B is a longitudinal cross-sectional view of Modification 2.

FIGS. 9A and 9B are cross-sectional views illustrating configurations of Modifications 3 and 4 of the multilayer substrate according to the second embodiment. FIG. 9A is a longitudinal cross-sectional view of Modification 3. FIG. 9B is a longitudinal cross-sectional view of Modification 4.

FIG. 10 is a longitudinal cross-sectional view of a multilayer substrate according to a third embodiment.

FIGS. 11A to 11C are transverse cross-sectional views of the multilayer substrate according to the third embodiment. FIG. 11A is a cross-sectional view taken along line E-E in FIG. 10. FIG. 11B is a cross-sectional view taken along line F-F in FIG. 10. FIG. 11C is a cross-sectional view taken along line G-G in FIG. 10.

FIG. 12 is a longitudinal cross-sectional view of Modification 1 of the multilayer substrate according to the third embodiment.

FIGS. 13A to 13C are transverse cross-sectional views of Modification 1 of the multilayer substrate according to the third embodiment. FIG. 13A is a cross-sectional view taken along line H-H in FIG. 12. FIG. 13B is a cross-sectional view taken along line I-I in FIG. 12. FIG. 13C is a cross-sectional view taken along line J-J in FIG. 12.

FIG. 14 is a longitudinal cross-sectional view of Modification 2 of the multilayer substrate according to the third embodiment.

FIG. 15 is a longitudinal cross-sectional view of a multilayer substrate according to a fourth embodiment.

FIGS. 16A and 16B are cross-sectional views illustrating configurations of Modifications 1 and 2 of the multilayer substrate according to the fourth embodiment. FIG. 16A is a longitudinal cross-sectional view of Modification 1. FIG. 16B is a longitudinal cross-sectional view of Modification 2.

FIGS. 17A to 17C are cross-sectional views illustrating a configuration of Modification 3 of the multilayer substrate according to the fourth embodiment. FIG. 17A is a longitudinal cross-sectional view of Modification 3. FIG. 17B is a cross-sectional view taken along line K-K in FIG. 17A. FIG. 17C is a cross-sectional view taken along line L-L in FIG. 17A.

FIGS. 18A and 18B are longitudinal cross-sectional views of a multilayer substrate according to a fifth embodiment. FIG. 18A is a cross-sectional view illustrating a non-conductive state of a magnet. FIG. 18B is a cross-sectional view illustrating a conductive state of the magnet.

FIGS. 19A to 19D are transverse cross-sectional views of the multilayer substrate according to the fifth embodiment. FIG. 19A is a cross-sectional view taken along line M-M in FIG. 18A. FIG. 19B is a cross-sectional view taken along line N-N in FIG. 18A. FIG. 19C is a cross-sectional view taken along line O-O in FIG. 18A. FIG. 19D is a cross-sectional view taken along line P-P in FIG. 18A.

FIGS. 20A to 20D are longitudinal cross-sectional views of Modifications 1 to 4 of the multilayer substrate according to the fifth embodiment.

FIG. 21 is a longitudinal cross-sectional view of a multilayer substrate according to a sixth embodiment.

FIG. 22 is a longitudinal cross-sectional view of a multilayer substrate according to a seventh embodiment.

FIG. 23 is a longitudinal cross-sectional view of Modification 1 of the multilayer substrate according to the seventh embodiment.

FIG. 24 is a longitudinal cross-sectional view of Modification 2 of the multilayer substrate according to the seventh embodiment.

FIGS. 25A and 25B are cross-sectional views of a multilayer substrate according to an eighth embodiment when a magnet has moved toward a right side of a hollow portion. FIG. 25A is a longitudinal cross-sectional view of the multilayer substrate according to the eighth embodiment. FIG. 25B is a cross-sectional view taken along line Q-Q in FIG. 25A.

FIGS. 26A and 26B are cross-sectional views of the multilayer substrate according to the eighth embodiment when the magnet moves toward a left side in the hollow portion. FIG. 26A is a longitudinal cross-sectional view of the multilayer substrate according to the eighth embodiment. FIG. 26B is a cross-sectional view taken along line R-R in FIG. 26A.

FIGS. 27A and 27B are cross-sectional views of a multilayer substrate according to a ninth embodiment when a magnet moves toward a right side of a hollow portion. FIG. 27A is a longitudinal cross-sectional view of the multilayer substrate according to the ninth embodiment. FIG. 27B is a cross-sectional view taken along line S-S in FIG. 27A.

FIGS. 28A and 28B are cross-sectional views of the multilayer substrate according to the ninth embodiment when the magnet moves toward a left side in the hollow portion. FIG. 28A is a longitudinal cross-sectional view of the multilayer substrate according to the ninth embodiment. FIG. 28B is a cross-sectional view taken along line T-T in FIG. 28A.

FIG. 29 is a longitudinal cross-sectional view of a multilayer substrate according to a tenth embodiment.

FIGS. 30A and 30B are cross-sectional views illustrating a configuration of a multilayer substrate according to an eleventh embodiment. FIG. 30A is a longitudinal cross-sectional view of the multilayer substrate according to the eleventh embodiment. FIG. 30B is a cross-sectional view taken along line U-U in FIG. 30A.

FIGS. 31A to 31C are cross-sectional views illustrating a configuration of a multilayer substrate according to a twelfth embodiment. FIG. 31A is a longitudinal cross-sectional view of the multilayer substrate according to the twelfth embodiment. FIG. 31B is a cross-sectional view taken along line V-V in FIG. 31A. FIG. 31C is a cross-sectional view taken along line W-W in FIG. 31A.

FIGS. 32A to 32C are cross-sectional views illustrating a configuration of Modification 1 of the multilayer substrate according to the twelfth embodiment. FIG. 32A is a longitudinal cross-sectional view of Modification 1. FIG. 32B is a cross-sectional view taken along line X-X in FIG. 32A. FIG. 32C is a cross-sectional view taken along line Y-Y in FIG. 32A.

FIG. 33 is a longitudinal cross-sectional view of Modification 2 of the multilayer substrate according to the twelfth embodiment.

FIG. 34 is a longitudinal cross-sectional view of a multilayer substrate according to a thirteenth embodiment.

FIGS. 35A to 35C are cross-sectional views illustrating a configuration of a multilayer substrate according to a fourteenth embodiment. FIG. 35A is a longitudinal cross-sectional view of the multilayer substrate according to the fourteenth embodiment. FIG. 35B is a cross-sectional view taken along line Z-Z in FIG. 35A. FIG. 35C is a cross-sectional view when a protrusion moves downward.

FIGS. 36A to 36C are cross-sectional views illustrating a modification of the multilayer substrate according to the fourteenth embodiment. FIG. 36A is a longitudinal cross-sectional view of Modification 1 of the multilayer substrate according to the fourteenth embodiment. FIG. 36B is a longitudinal cross-sectional view of Modification 2 of the multilayer substrate according to the fourteenth embodiment. FIG. 36C is a longitudinal cross-sectional view of Modification 3 of the multilayer substrate according to the fourteenth embodiment.

FIGS. 37A to 37C are cross-sectional views illustrating a configuration of a multilayer substrate according to a fifteenth embodiment. FIG. 37A is a longitudinal cross-sectional view of the multilayer substrate according to the fifteenth embodiment. FIG. 37B is a cross-sectional view taken along line A1-A1 in FIG. 37A. FIG. 37C is a cross-sectional view when a protrusion moves toward a right side.

FIG. 38 is a longitudinal cross-sectional view of Modification 1 of the multilayer substrate according to the fifteenth embodiment.

FIG. 39 is a longitudinal cross-sectional view of a multilayer substrate according to a sixteenth embodiment.

FIGS. 40A and 40B are cross-sectional views illustrating a configuration of a multilayer substrate according to a seventeenth embodiment. FIG. 40A is a longitudinal cross-sectional view of the multilayer substrate according to the seventeenth embodiment. FIG. 40B is a cross-sectional view taken along line B1-B1 in FIG. 40A.

FIG. 41 is a longitudinal cross-sectional view of a multilayer substrate according to an eighteenth embodiment.

### DESCRIPTION OF EMBODIMENTS

Hereinafter, in order to describe the present disclosure in more detail, modes for carrying out the present disclosure will be described with reference to the accompanying drawings. Note that configurations having functions similar to those described in a preceding embodiment are denoted by the same reference numerals, and description thereof will be omitted.

### First Embodiment

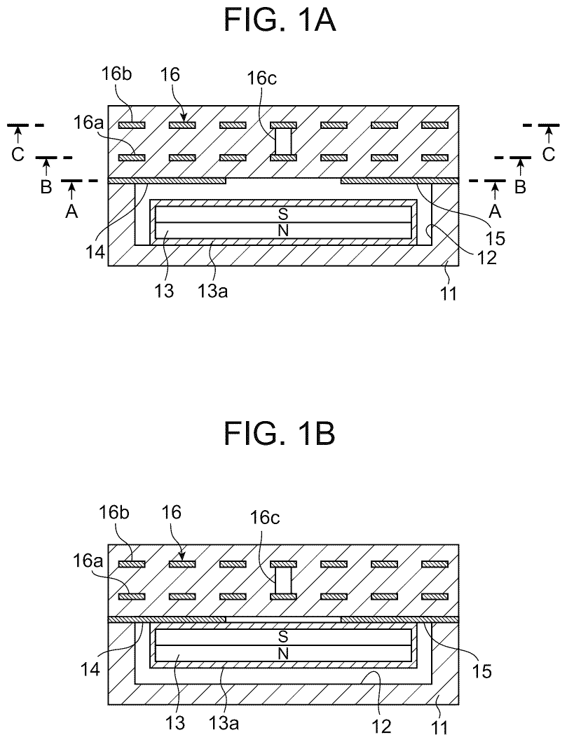

A multilayer substrate according to a first embodiment will be described with reference to FIGS. 1A and 1B to FIG. 6.

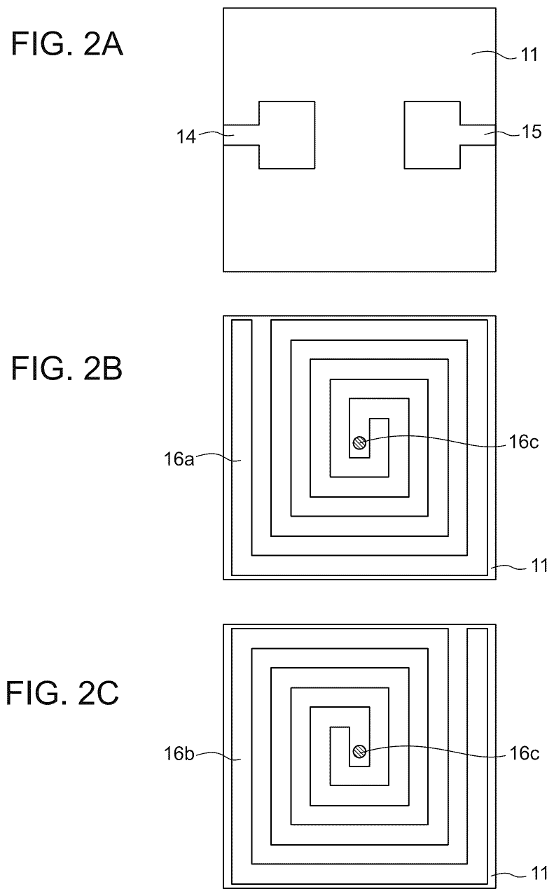

FIGS. 1A and 1B are longitudinal cross-sectional views of a multilayer substrate according to the first embodiment. FIGS. 2A to 2C are transverse cross-sectional views of the multilayer substrate according to the first embodiment.

As illustrated in FIGS. 1A and 1B and FIGS. 2A to 2C, the multilayer substrate according to the first embodiment includes a substrate body 11, a hollow portion 12, a magnet 13 serving as a movable unit, a first switch conductor pattern 14, a second switch conductor pattern 15, and a coil 16. Note that a thickness direction of the multilayer substrate and a vertical direction of the multilayer substrate are the same direction.

The substrate body 11 is formed of, for example, resin or ceramics. That is, the multilayer substrate according to the first embodiment is a resin multilayer substrate or a ceramic multilayer substrate. Then, the hollow portion 12 is formed inside the substrate body 11. The length, width, and height (thickness) of the hollow portion 12 are each formed with a dimension of several tens μm to several tens mm.

The magnet 13 is provided inside the hollow portion 12 to be movable in the vertical direction. Here, a magnetic pole of an upper half of the magnet 13 serving as the magnetic body is the S pole, and a magnetic pole of a lower half of the magnet 13 is the N pole. Further, the entire surface of the magnet 13 is plated with a conductor. The portion plated with the conductor is hereinafter referred to as conductor plating 13a. Note that the magnet 13 is, for example, a ferrite magnet, a samarium-cobalt magnet, a neodymium magnet, or the like. The conductor plating 13a serving as the conductor layer is, for example, nickel-gold plating. The conductor plating 13a may be omitted when the magnet 13 is a good conductor magnet.

A pair of the first switch conductor patterns 14 and the second switch conductor patterns 15 are provided on a left side and a right side of a top surface of the hollow portion 12, respectively. The first switch conductor pattern 14 arranged on the left side and the second switch conductor pattern 15 arranged on the right side do not overlap each other in the thickness direction of the substrate body 11. The first switch conductor pattern 14 and the second switch conductor pattern 15 are arranged with a predetermined amount of a gap in a width direction of the substrate body 11. A narrow portion of the first switch conductor pattern 14 is provided inside the left side of the substrate body 11. Further, a wide portion thereof is exposed to the inside of the hollow portion 12 and faces an upper surface of the magnet 13. On the other hand, a narrow substrate of the second switch conductor pattern 15 is provided inside the right side of the substrate body 11. Further, a wide portion thereof is exposed to the inside of the hollow portion 12 and faces the upper surface of the magnet 13.

The coil 16 is provided above the first switch conductor pattern 14 and the second switch conductor pattern 15 in the substrate body 11. The coil 16 generates a magnetic field for moving the magnet 13 serving as a movable unit. Further, the coil 16 includes a lower layer coil conductor pattern 16a, an upper layer coil conductor pattern 16b, and a via 16c.

The lower layer coil conductor pattern 16a and the upper layer coil conductor pattern 16b are formed in a coil shape. The lower layer coil conductor pattern 16a is disposed below the upper layer coil conductor pattern 16b. A winding direction of the lower layer coil conductor pattern 16a and a winding direction of the upper layer coil conductor pattern 16b are opposite to each other. The via 16c forms a central axis of the coil 16. The via 16c connects a center end of the lower layer coil conductor pattern 16a and a center end of the upper layer coil conductor pattern 16b.

Therefore, when a voltage is applied between an outer end of the lower layer coil conductor pattern 16a and an outer end of the upper layer coil conductor pattern 16b, a current flows through the lower layer coil conductor pattern 16a, the upper layer coil conductor pattern 16b, and the via 16c. Thus, magnetic poles are formed in the thickness direction of the coil 16. At this time, by changing the direction of the current flowing through the coil 16, the magnetic pole formed in the coil 16 is switched.

As illustrated in FIG. 1A, in a state where the magnet 13 is disposed on a bottom surface of the hollow portion 12, when a current flows through the coil 16 in such a manner that the N pole is formed on a lower side of the coil 16 while the S pole is formed on an upper side of the coil 16, the S pole of the magnet 13 is attracted to the N pole formed on the coil 16. Thus, as illustrated in FIG. 1B, the magnet 13 rises from the bottom surface of the hollow portion 12 and comes into contact with the first switch conductor pattern 14 and the second switch conductor pattern 15. At this time, since the conductor plating 13a is applied to the surface of the magnet 13, the first switch conductor pattern 14 and the second switch conductor pattern 15 are electrically connected. That is, the first switch conductor pattern 14 and the second switch conductor pattern 15 become turned on.

Further, by changing the direction of the current flowing through the coil 16 from the state of FIG. 1B described above, the S pole is formed on the lower side of the coil 16, and the N pole is formed on the upper side of the coil 16. Thus, the S pole of magnet 13 and the S pole formed in the coil 16 repel each other. As a result, as illustrated in FIG. 1A, the magnet 13 falls away from the first switch conductor pattern 14 and the second switch conductor pattern 15, and is seated on the bottom surface of the hollow portion 12. Therefore, the first switch conductor pattern 14 and the second switch conductor pattern 15 are non-conductive. That is, the first switch conductor pattern 14 and the second switch conductor pattern 15 become turned off.

Therefore, in the multilayer substrate according to the first embodiment, the magnet 13 serving as the movable unit can be moved in the vertical direction of the hollow portion 12 inside the hollow portion 12 formed to have a side of several tens of μm to several tens of mm. It is difficult to manufacture the hollow portion 12 and the magnet 13 even using the semiconductor manufacturing technology and the MEMS technology. In addition, in the multilayer substrate according to the first embodiment, the coil 16 having a complicated three-dimensional structure can be easily formed around the hollow portion 12. On the other hand, it is difficult to manufacture the coil 16 even using the semiconductor manufacturing technology and the MEMS technology.

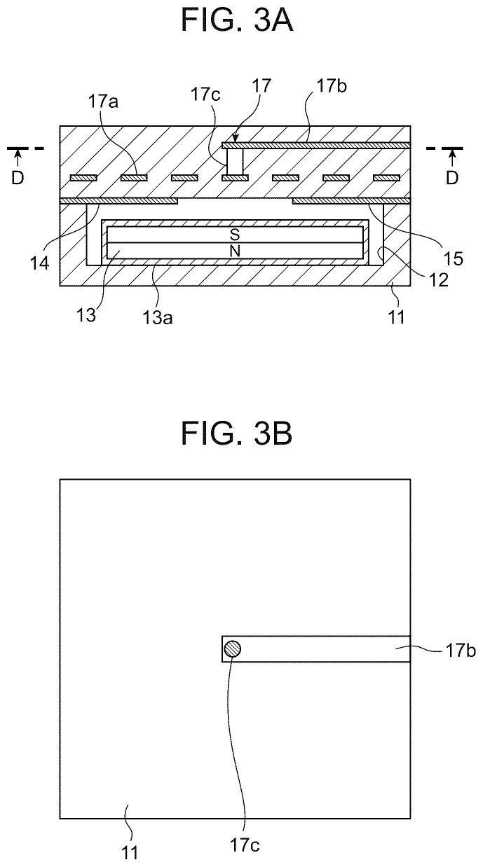

Next, modifications of the multilayer substrate according to the first embodiment will be described with reference to FIGS. 3A and 3B to FIG. 6.

FIGS. 3A and 3B are cross-sectional views illustrating a configuration of Modification 1 of the multilayer substrate according to the first embodiment. As illustrated in FIGS. 3A and 3B, the multilayer substrate according to the first embodiment may include a single-layer coil 17 instead of the two-layer coil 16. The coil 17 includes a coil conductor pattern 17a, an extended conductor pattern 17b, and a via 17c. The coil conductor pattern 17a is provided above the hollow portion 12. The extended conductor pattern 17b is formed in a straight line from a center portion toward a side portion of the substrate body 11. One end of the extended conductor pattern 17b is disposed at the center portion of the substrate body 11. The other end of the extended conductor pattern 17b is exposed from a side face of the substrate body 11. The via 17c is a central axis of the coil 17. The via 17c connects a center end of the coil conductor pattern 17a and the one end of the extended conductor pattern 17b.

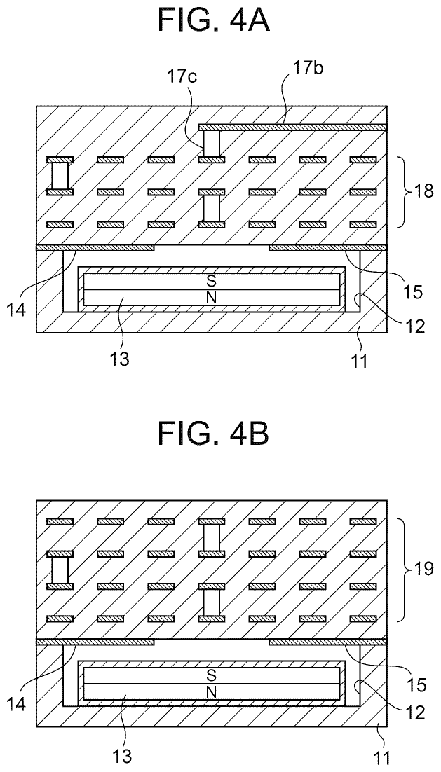

FIGS. 4A and 4B are cross-sectional views illustrating configurations of Modifications 2 and 3 of the multilayer substrate according to the first embodiment. As illustrated in FIG. 4A, the multilayer substrate according to the first embodiment may include a three-layer coil 18 instead of the two-layer coil 16. In addition, as illustrated in FIG. 4B, the multilayer substrate according to the first embodiment may include a nine-layer coil 19 instead of the two-layer coil 16. However, when the effect of increasing the magnetic force of the extended conductor pattern 17b is poor, the extended conductor pattern 17b is preferably applied to the coil of an even number layer because the coil of the even number layer can use the substrate area more than the coil of the odd number layer.

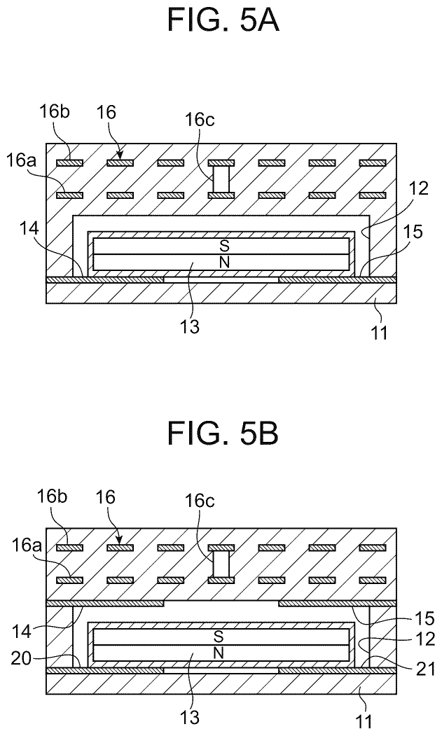

FIGS. 5A and 5B are cross-sectional views illustrating configurations of Modifications 4 and 5 of the multilayer substrate according to the first embodiment. As illustrated in FIG. 5A, in the multilayer substrate according to the first embodiment, the first switch conductor pattern 14 and the second switch conductor pattern 15 may be provided on a left side and a right side of the bottom surface of the hollow portion 12, respectively. In addition, as illustrated in FIG. 5B, in the multilayer substrate according to the first embodiment, a third switch conductor pattern 20 and a fourth switch conductor pattern 21 may be provided on the left side and the right side of the bottom surface of the hollow portion 12, respectively. In this case, it is only necessary to use one of the set of the first switch conductor pattern 14 and the second switch conductor pattern 15 and the set of the third switch conductor pattern 20 and the fourth switch conductor pattern 21 in a switch ON state, and to use the other pair in a switch OFF state.

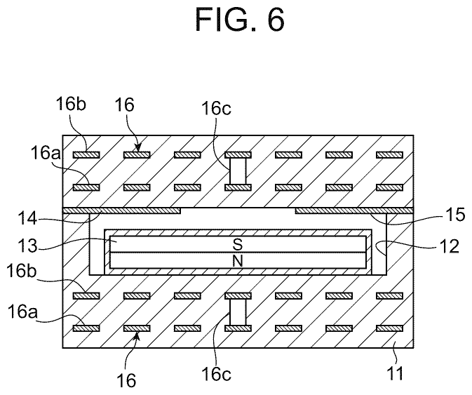

FIG. 6 is a longitudinal cross-sectional view of Modification 6 of the multilayer substrate according to the first embodiment. As illustrated in FIG. 6, in the multilayer substrate according to the first embodiment, not only the coil (upper coil) 16 may be provided above the hollow portion 12, but also the coil (lower coil) 16 may be further provided below the hollow portion 12.

Note that a lubricant may be applied to the surface of the hollow portion 12. In this case, the multilayer substrate according to the first embodiment can suppress frictional force and wear generated when the magnet 13 moves.

### Second Embodiment

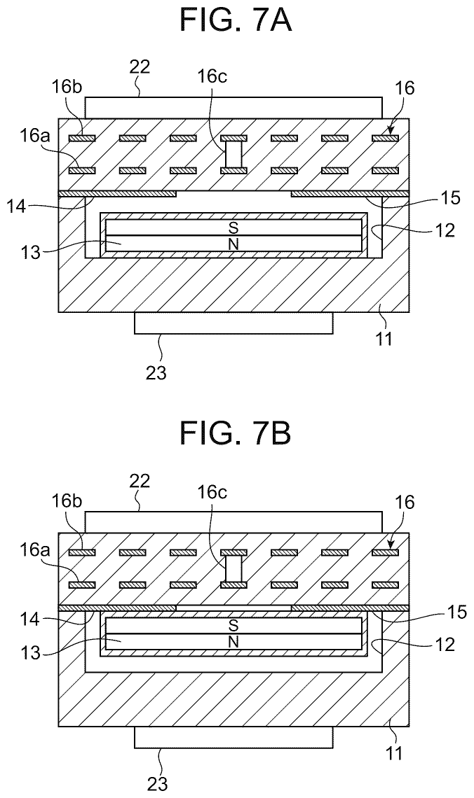

A multilayer substrate according to a second embodiment will be described with reference to FIGS. 7A and 7B to FIGS. 9A and 9B.

FIGS. 7A and 7B are longitudinal cross-sectional views of the multilayer substrate according to the second embodiment. As illustrated in FIG. 7, the multilayer substrate according to the second embodiment includes an upper yoke 22 and a lower yoke 23 in addition to the configuration of the multilayer substrate according to the first embodiment illustrated in FIG. 1.

The upper yoke 22 is provided on an upper surface of the substrate body 11. The lower yoke 23 is provided on a lower surface of the substrate body 11. The upper yoke 22 and the lower yoke 23 are, for example, soft magnetic bodies such as SUS430. The soft magnetic body is strongly magnetized under the influence of a magnetic field, does not have a magnetic force when there is no magnetic field, and has a role of concentrating the magnetic field.

The upper yoke 22 and the lower yoke 23 are designed in such a manner that attractive force generated between a magnet 13 and a coil 16 is larger than attractive force generated between the magnet 13 and the yokes 22 and 23. When the attractive force generated between the magnet 13 and the yokes 22 and 23 is larger than the attractive force generated between the magnet 13 and the coil 16, it is only necessary that thicknesses of the yokes 22 and 23 and contact areas thereof with the substrate body 11 are reduced, or distances of the yokes 22 and 23 from the coil 16 are increased.

FIGS. 7A and 7B illustrate an example in which the contact area of the lower yoke 23 disposed far from the coil 16 with the substrate body 11 is smaller than the contact area of the upper yoke 22 disposed close to the coil 16 with the substrate body 11. This is because, when the magnet 13 is disposed on the bottom surface of the hollow portion 12, the magnet 13 is farther from the coil 16, so that the attractive force generated between the magnet 13 and the coil 16 decreases.

Further, the attractive force generated between the magnet 13 and the upper yoke 22 at a position where the magnet 13 is closest to the upper yoke 22 is larger than the attractive force generated between the magnet 13 and the lower yoke 23 at the position. On the other hand, the attractive force generated between the magnet 13 and the lower yoke 23 at a position where the magnet 13 is closest to the lower yoke 23 is larger than the attractive force generated between the magnet 13 and the upper yoke 22 at the position.

Furthermore, the attractive force generated between the magnet 13 and the upper yoke 22 at the position where the magnet 13 is closest to the upper yoke 22 and the attractive force generated between the magnet 13 and the lower yoke 23 at the position where the magnet 13 is closest to the lower yoke 23 are made larger than gravity acting on the magnet 13.

Therefore, as illustrated in FIG. 7A, the magnet 13 is disposed on the bottom surface of the hollow portion 12 by the attractive force generated between the magnet 13 and the lower yoke 23. Then, a current flows through the coil 16 in such a manner that the attractive force generated between the magnet 13 and the coil 16 is larger than the attractive force generated between the magnet 13 and the lower yoke 23. Thus, as illustrated in FIG. 7B, the magnet 13 rises from the bottom surface of the hollow portion 12 and comes into contact with the first switch conductor pattern 14 and the second switch conductor pattern 15. As a result, the first switch conductor pattern 14 and the second switch conductor pattern 15 are conducted.

At this time, even if the current flowing through the coil 16 is stopped, the contact with the first switch conductor pattern 14 and the second switch conductor pattern 15 is maintained by the attractive force generated between the magnet 13 and the upper yoke 22. Thus, the switch is maintained in an ON state.

Therefore, in the multilayer substrate according to the second embodiment, the magnet 13 can keep in contact with the first switch conductor pattern 14 and the second switch conductor pattern 15 without applying a current to the coil 16. Thus, the multilayer substrate according to the second embodiment can suppress power consumption and heat generation.

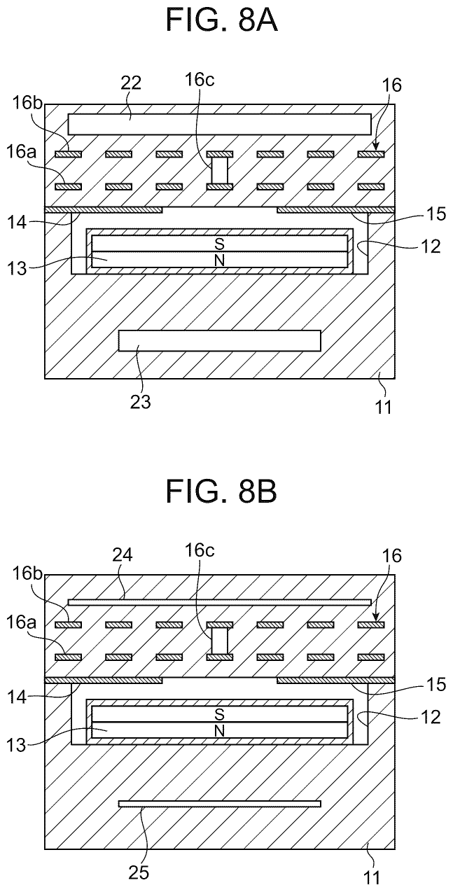

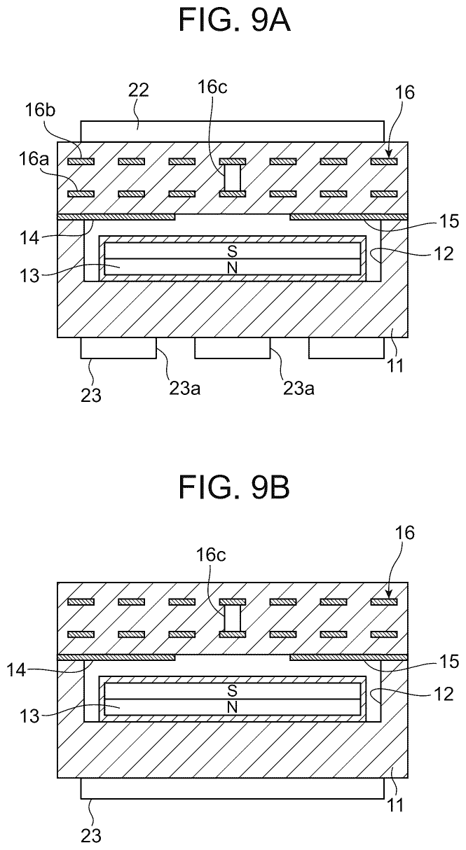

Next, a modification of the multilayer substrate according to the second embodiment will be described with reference to FIGS. 8A and 8B and FIGS. 9A and 9B.

FIGS. 8A and 8B are cross-sectional views illustrating configurations of Modifications 1 and 2 of the multilayer substrate according to the second embodiment. As illustrated in FIG. 8A, in the multilayer substrate according to the second embodiment, the upper yoke 22 and lower yoke 23 may be embedded in the substrate body 11. In addition, as illustrated in FIG. 8B, in the multilayer substrate according to the second embodiment, an upper yoke pattern 24 and a lower yoke pattern 25 may be embedded in the substrate body 11. The upper yoke pattern 24 and the lower yoke pattern 25 are provided on the substrate body 11 using, for example, a stainless foil formed of SUS430 which is a soft magnetic body by using a stainless etching technique.

FIG. 9A and B are cross-sectional views illustrating configurations of Modifications 3 and 4 of the multilayer substrate according to the second embodiment. As illustrated in FIG. 9A, in the multilayer substrate according to the second embodiment, the magnitude of the attractive force generated between the magnet 13 and the lower yoke 23 may be adjusted by providing an adjustment hole 23a serving as a through hole in the thickness direction with respect to the lower yoke 23. In addition, as illustrated in FIG. 9B, the multilayer substrate according to the second embodiment may include one of the upper yoke 22 and the lower yoke 23. In this case, it is preferable to provide a yoke on the side where the time for holding the magnet 13 is long.

### Third Embodiment

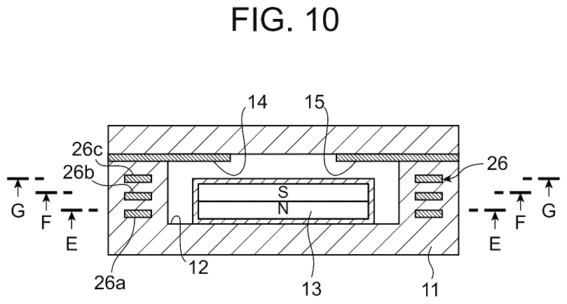

A multilayer substrate according to a third embodiment will be described with reference to FIGS. 10 to 14.

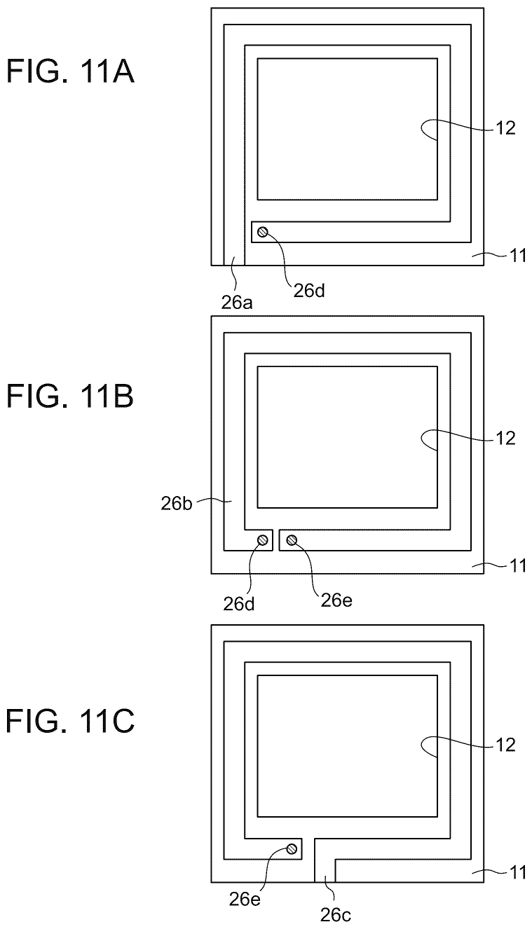

FIG. 10 is a longitudinal cross-sectional view of the multilayer substrate according to the third embodiment. FIGS. 11A to 11C are transverse cross-sectional views of the multilayer substrate according to the third embodiment. Note that, in FIGS. 11A to 11C, the magnet 13 is omitted. As illustrated in FIG. 10 and FIGS. 11A to 11C, the multilayer substrate according to the third embodiment includes a three-layer coil 26 instead of the coil 16 of the multilayer substrate according to the first embodiment illustrated in FIGS. 1A and 1B.

The coil 26 is provided in such a way as to surround a periphery of a side face of a hollow portion 12. The coil 26 includes a lower layer coil conductor pattern 26a, a middle layer coil conductor pattern 26b, an upper layer coil conductor pattern 26c, and vias 26d and 26e. The lower layer coil conductor pattern 26a, the middle layer coil conductor pattern 26b, and the upper layer coil conductor pattern 26c are arranged in this order from a lower side to an upper side. In addition, these are formed in a coil shape of one turn.

One end of the lower layer coil conductor pattern 26a is exposed from a side face of the substrate body 11. The other end of the lower layer coil conductor pattern 26a and one end of the middle layer coil conductor pattern 26b are connected by the via 26d. The other end of the middle layer coil conductor pattern 26b and one end of the upper layer coil conductor pattern 26c are connected by the via 26e. The other end of the upper layer coil conductor pattern 26c is exposed from the side face of the substrate body 11.

Therefore, when a voltage is applied between the one end of the lower layer coil conductor pattern 26a and the other end of the upper layer coil conductor pattern 26c, a current flows through the lower layer coil conductor pattern 26a, the middle layer coil conductor pattern 26b, the upper layer coil conductor pattern 26c, and the vias 26d and 26e. Thus, magnetic poles are formed in the thickness direction of the coil 26. At this time, by changing the direction of the current flowing through the coil 26, the magnetic pole formed in the coil 26 is switched.

Therefore, in the multilayer substrate according to the third embodiment, by providing the coil 26 in such a way as to surround the periphery of the side face of the hollow portion 12, it is possible to obtain attractive force generated between the magnet 13 and the coil 26 with a smaller number of windings of the coil 26.

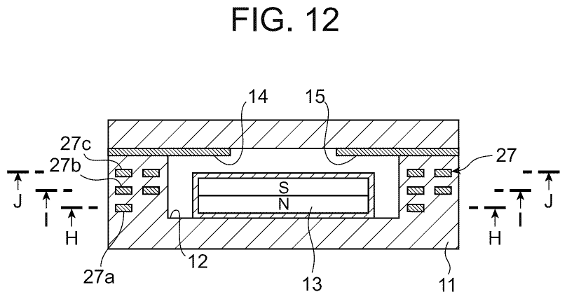

Next, modifications of the multilayer substrate according to the third embodiment will be described with reference to FIGS. 12 to 14.

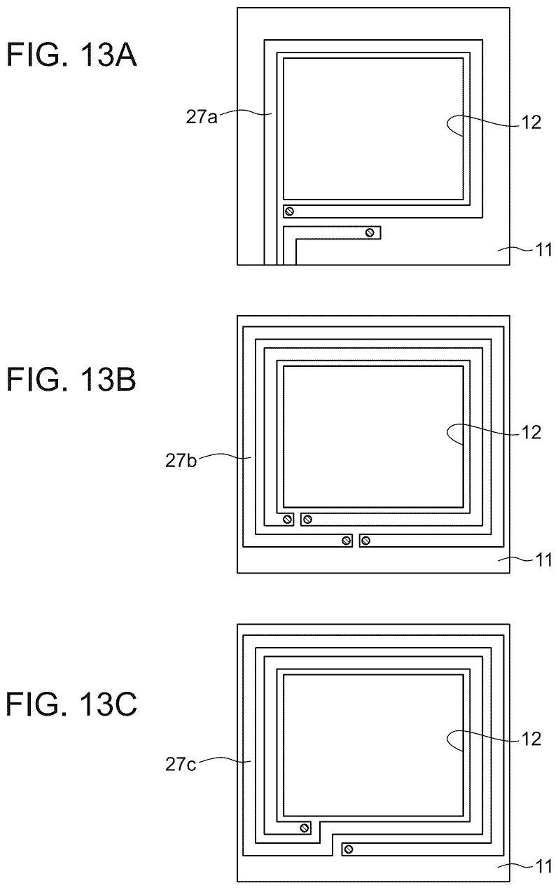

FIG. 12 is a longitudinal cross-sectional view of Modification 1 of the multilayer substrate according to the third embodiment. FIGS. 13A to 13C are transverse cross-sectional views of Modification 1 of the multilayer substrate according to the third embodiment. Note that, in FIG. 13, the magnet 13 is omitted. As illustrated in FIG. 12 and FIGS. 13A to 13C, the multilayer substrate according to the third embodiment includes a three-layer coil 27 instead of the three-layer coil 26. The coil 27 includes a lower layer coil conductor pattern 27a, a middle layer coil conductor pattern 27b, an upper layer coil conductor pattern 27c, and a via. These are formed in a coil shape of two turns.

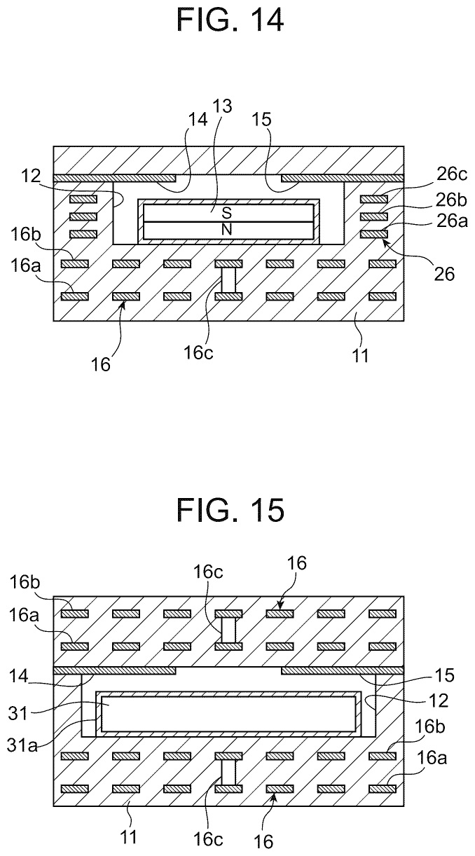

FIG. 14 is a longitudinal cross-sectional view of Modification 2 of the multilayer substrate according to the third embodiment. As illustrated in FIG. 14, the multilayer substrate according to the third embodiment is obtained by adding the coil 16 constituting the lower coil in the multilayer substrate according to the first embodiment.

### Fourth Embodiment

A multilayer substrate according to a fourth embodiment will be described with reference to FIG. 15 to FIGS. 17A to 17C.

FIG. 15 is a longitudinal cross-sectional view of the multilayer substrate according to the fourth embodiment. As illustrated in FIG. 15, the multilayer substrate according to the fourth embodiment includes a yoke 31 serving as a movable unit instead of the magnet 13 of Modification 6 of the multilayer substrate according to the first embodiment illustrated in FIG. 6. The yoke 31 is provided inside a hollow portion 12. Further, the entire surface of the yoke 31 is plated with a conductor. The portion plated with the conductor is hereinafter referred to as conductor plating 31a.

As illustrated in FIG. 15, when the yoke 31 is disposed on a bottom surface of the hollow portion 12, a current flows through an upper coil 16 while no current flows through a lower coil 16. The yoke 31 rises from the bottom surface of the hollow portion 12 and comes into contact with a first switch conductor pattern 14 and a second switch conductor pattern 15. At this time, since the conductor plating 31a is applied to the surface of the yoke 31, the first switch conductor pattern 14 and the second switch conductor pattern 15 are electrically connected. That is, the first switch conductor pattern 14 and the second switch conductor pattern 15 become turned on.

Therefore, since the multilayer substrate according to the fourth embodiment includes the yoke 31 as the movable unit, the multilayer substrate is less likely to crack and can be downsized as compared with the magnet 13.

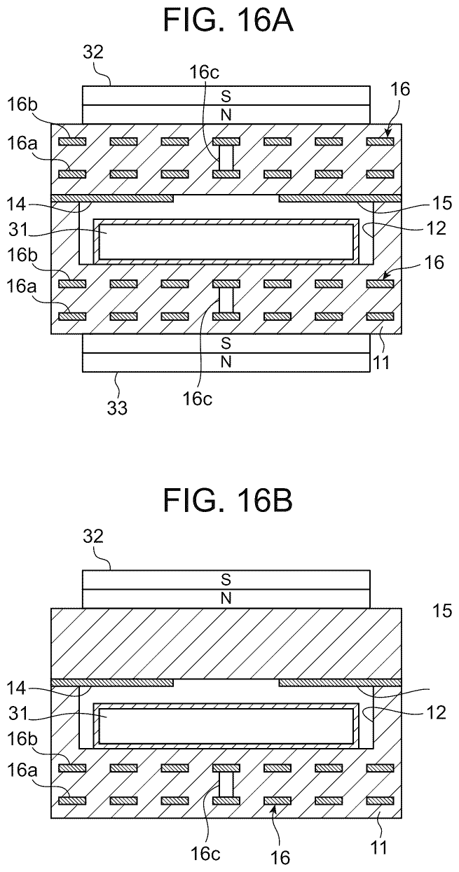

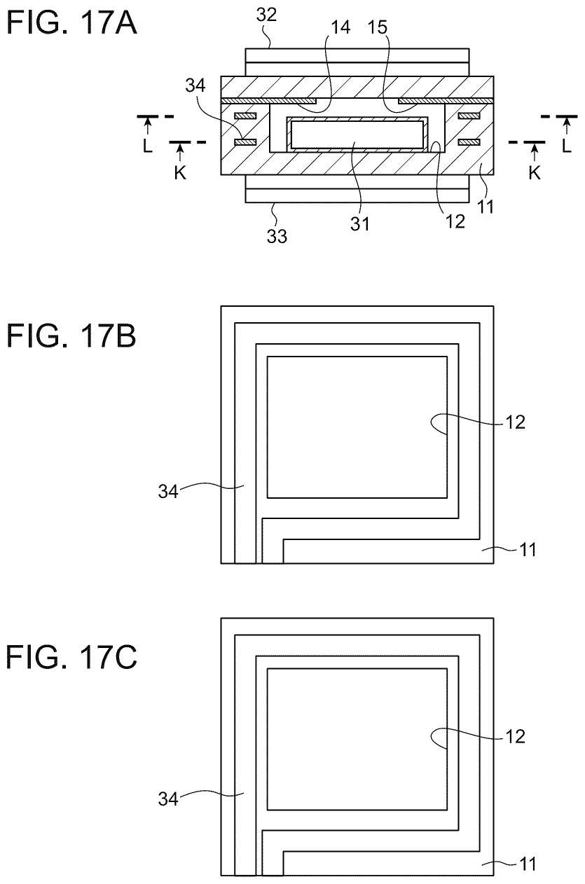

Next, a modification of the multilayer substrate according to the fourth embodiment will be described with reference to FIGS. 16A and 16B and FIGS. 17A to 17C.

FIGS. 16A and 16B are cross-sectional views illustrating configurations of Modifications 1 and 2 of the multilayer substrate according to the fourth embodiment. As illustrated in FIG. 16A, Modification 1 of the multilayer substrate according to the fourth embodiment is obtained by adding an upper magnet 32 and a lower magnet 33 to the configuration of the multilayer substrate according to the fourth embodiment. The upper magnet 32 is provided on an upper surface of the substrate body 11. The lower magnet 33 is provided on a lower surface of the substrate body 11.

Therefore, even when the current flowing through the upper coil 16 is stopped, the yoke 31 maintains contact between the first switch conductor pattern 14 and the second switch conductor pattern 15 by attractive force generated between the yoke 31 and the upper magnet 32. Thus, the switch is maintained in an ON state.

Therefore, in the multilayer substrate according to the fourth embodiment, the yoke 31 can keep in contact with the first switch conductor pattern 14 and the second switch conductor pattern 15 without applying a current to flow in the upper coil 16. Thus, the multilayer substrate according to the fourth embodiment can suppress power consumption and heat generation.

In addition, as illustrated in FIG. 16B, the multilayer substrate according to the fourth embodiment may be provided with any one of the set of the lower coil 16 and the upper magnet 32 and the set of the upper coil 16 and the lower magnet 33.

FIGS. 17A to 17C are cross-sectional views illustrating a configuration of Modification 3 of the multilayer substrate according to the fourth embodiment. Note that, in FIGS. 17B and 17C, the yoke 31 is omitted. As illustrated in FIGS. 17A to 17C, the multilayer substrate according to the fourth embodiment may include a coil 34 instead of the coil 16. The coil 34 is provided in such a way as to surround a periphery of a side face of the hollow portion 12. The coil 34 includes two layers, and each layer is formed of one turn.

Therefore, in the multilayer substrate according to the fourth embodiment, by providing the coil 34 in such a way as to surround the periphery of the side face of the hollow portion 12, attractive force generated between the yoke 31 and the coil 34 can be obtained with a smaller number of windings of the coil 34.

### Fifth Embodiment

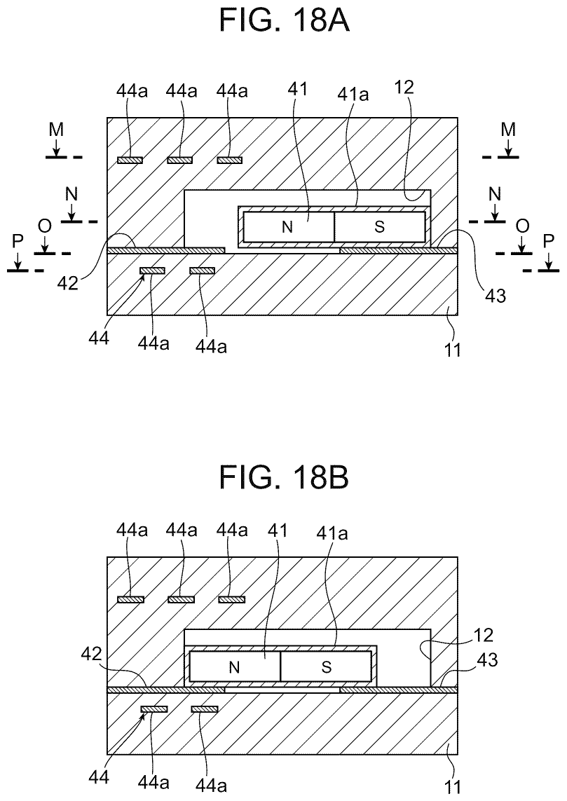

A multilayer substrate according to a fifth embodiment will be described with reference to FIGS. 18A and 18B to FIGS. 20A to 20D.

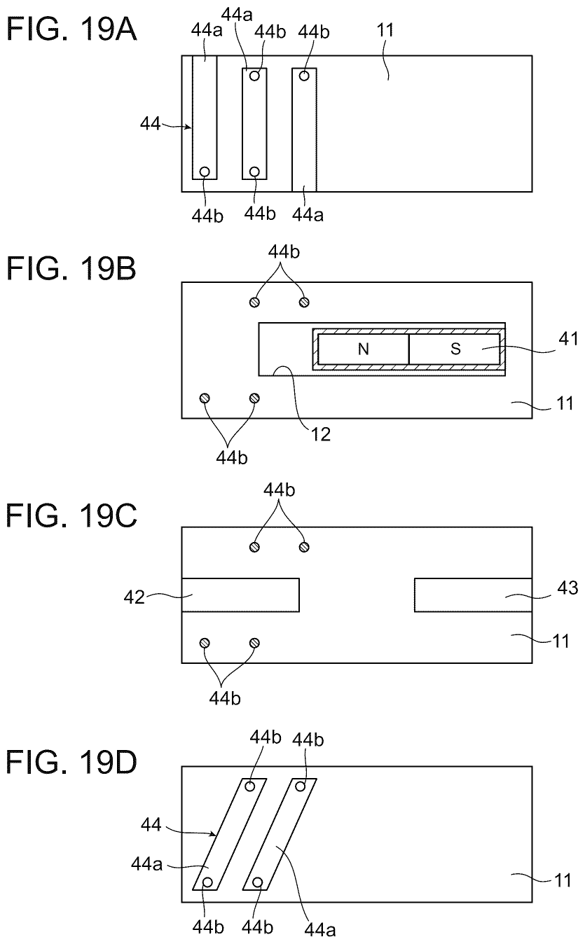

FIGS. 18A and 18B is a longitudinal cross-sectional view of the multilayer substrate according to the fifth embodiment. FIGS. 19A to 19D are transverse cross-sectional views of the multilayer substrate according to the fifth embodiment.

As illustrated in FIGS. 18A and 18B and FIGS. 19A to 19D, the multilayer substrate according to the fifth embodiment includes a substrate body 11, a hollow portion 12, a magnet 41, a first switch conductor pattern 42, a second switch conductor pattern 43, and a coil 44.

The magnet 41 is provided inside the hollow portion 12 to be movable in a width direction. Here, a magnetic pole on a left side in the width direction of the magnet 41 serving as a magnetic body is an N pole, and a magnetic pole on a right side in the width direction of the magnet 41 is an S pole. Further, the entire surface of the magnet 41 is plated with a conductor. The portion plated with the conductor is hereinafter referred to as conductor plating 41a.

A pair of the first switch conductor pattern 42 and the second switch conductor pattern 43 are provided on a left side and a right side of a bottom surface of the hollow portion 12, respectively. The first switch conductor pattern 42 disposed on a left side and the second switch conductor pattern 43 disposed on a right side do not overlap each other in the width direction of the substrate body 11. The first switch conductor pattern 42 and the second switch conductor pattern 43 are arranged with a predetermined amount of gap in the width direction of the substrate body 11.

The coil 44 is provided in such a way as to surround the top surface and the bottom surface of the hollow portion 12, and further, an upper surface and a lower surface of the first switch conductor pattern 42. Specifically, the coil 44 includes a plurality of coil conductor patterns 44a and a plurality of vias 44b connecting the coil conductor patterns. The plurality of coil conductor patterns 44a is substantially parallel to the top surface and the bottom surface of the hollow portion 12 and the upper surface and the lower surface of the first switch conductor pattern 42. Further, the plurality of vias 44b is arranged in such a way as to extend in a vertical direction of the substrate body 11.

Therefore, when a voltage is applied between one end and the other end of the coil 44, a current flows through the coil 44. Thus, a magnetic pole is formed in the axial direction (in other words, in the width direction of the substrate body 11) of the coil 44. That is, magnetic poles are formed on a left side and a right side of the coil 44.

As illustrated in FIG. 18A, in a state where the magnet 41 is located on the right side of the hollow portion 12 and is in contact with the second switch conductor pattern 43, when a current flows through the coil 44 in such a manner that the right side of the coil 44 becomes the S pole, the N pole of the magnet 41 is attracted to the S pole of the coil 44. Thus, as illustrated in FIG. 18B, the magnet 41 moves toward the left side in the hollow portion 12, and comes into contact with the first switch conductor pattern 42 while coming into contact with the second switch conductor pattern 43. As a result, the first switch conductor pattern 42 and the second switch conductor pattern 43 are conducted. That is, the first switch conductor pattern 42 and the second switch conductor pattern 43 become turned on.

On the other hand, by changing the direction of the current flowing to the coil 44, the right side of the coil 44 becomes the N pole, and the N pole of the magnet 41 and the N pole formed in the coil 44 repel each other. As a result, as illustrated in FIG. 18A, the magnet 41 moves toward the right side of the hollow portion 12, separates from the first switch conductor pattern 42, and contacts only the second switch conductor pattern 43. Therefore, the first switch conductor pattern 42 and the second switch conductor pattern 43 are non-conductive. That is, the first switch conductor pattern 42 and the second switch conductor pattern 43 become turned off.

Therefore, in the multilayer substrate according to the fifth embodiment, the magnet 41 serving as the movable unit can be moved in the width direction of the hollow portion 12 inside the hollow portion 12 formed to have a side of several tens of μm to several tens of mm. It is difficult to manufacture such hollow portion 12 and magnet 41 even using the semiconductor manufacturing technology and the MEMS technology. In addition, in the multilayer substrate according to the fifth embodiment, the coil 44 having a complicated three-dimensional structure can be easily formed around the hollow portion 12. On the other hand, it is difficult to manufacture the coil 44 even using the semiconductor manufacturing technology and the MEMS technology.

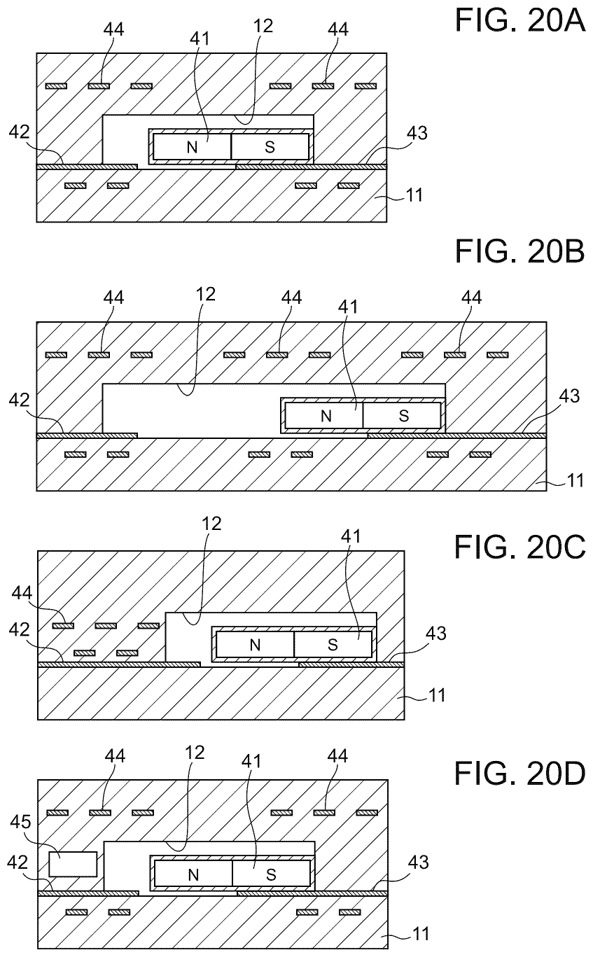

Next, a modification of the multilayer substrate according to the fifth embodiment will be described with reference to FIGS. 20A to 20D. FIGS. 20A to 20D are longitudinal cross-sectional views of Modifications 1 to 4 of the multilayer substrate according to the fifth embodiment.

As illustrated in FIG. 20A, in the multilayer substrate according to the fifth embodiment, the coil 44 may also be provided on the right side of the hollow portion 12. Thus, in the multilayer substrate according to the fifth embodiment, one coil 44 can be used for attraction of the magnet 41, and the other coil 44 can be used for repulsion of the magnet 41.

In addition, as illustrated in FIG. 20B, in the multilayer substrate according to the fifth embodiment, the coil 44 may be provided in the central portion of the hollow portion 12.

In addition, as illustrated in FIG. 20C, in the multilayer substrate according to the fifth embodiment, the coil 44 may be provided on a side of the hollow portion 12.

Furthermore, as illustrated in FIG. 20D, in the multilayer substrate according to the fifth embodiment, a magnetic body 45 may be provided inside the coil 44. Thus, in the multilayer substrate according to the fifth embodiment, the moving position can be held even when no current flows through the coil 44.

### Sixth Embodiment

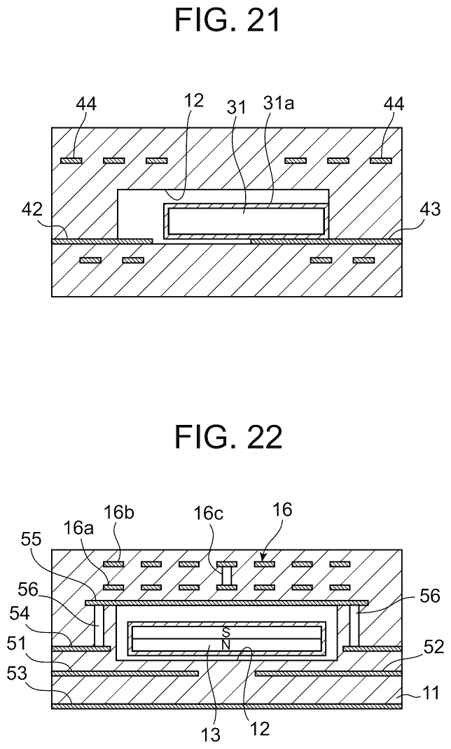

Next, a multilayer substrate according to a sixth embodiment will be described with reference to FIG. 21. FIG. 21 is a longitudinal cross-sectional view of the multilayer substrate according to the sixth embodiment.

As illustrated in FIG. 21, the multilayer substrate according to the sixth embodiment includes a yoke 31 instead of the magnet 41 of Modification 1 of the multilayer substrate according to the fifth embodiment illustrated in FIG. 20A. Therefore, since the multilayer substrate according to the sixth embodiment includes the yoke 31 as a movable unit, the multilayer substrate is less likely to crack and can be downsized as compared with the magnet 41.

Note that, in the sixth embodiment, a coil may be provided on one of a left side and a right side of the hollow portion 12, and a magnetic body may be provided on one of the left side and the right side of the hollow portion 12.

### Seventh Embodiment

A multilayer substrate according to a seventh embodiment will be described with reference to FIGS. 22 to 24.

FIG. 22 is a longitudinal cross-sectional view of the multilayer substrate according to the seventh embodiment. As illustrated in FIG. 22, the multilayer substrate according to the seventh embodiment includes a substrate body 11, a hollow portion 12, a magnet 13, a coil 16, a first strip line pattern 51, a second strip line pattern 52, a first ground pattern 53, a second ground pattern 54, a third ground pattern 55, and a plurality of vias 56. The first strip line pattern 51, the second strip line pattern 52, the first ground pattern 53, the second ground pattern 54, the third ground pattern 55, and the plurality of vias 56 are provided inside the substrate body 11.

The first strip line pattern 51 and the second strip line pattern 52 are provided below the hollow portion 12. The first strip line pattern 51 is arranged on a left side of the hollow portion 12. The second strip line pattern 52 is arranged on a right side of the hollow portion 12. Further, the first ground pattern 53 is disposed below the substrate body 11. The second ground pattern 54 is disposed around a side face of the hollow portion 12. The first strip line pattern 51 and the second strip line pattern 52 are disposed between the first ground pattern 53 and the second ground pattern 54 in the vertical direction.

The third ground pattern 55 is disposed above the second ground pattern 54. The third ground pattern 55 is provided in such a way as to form a top surface of the hollow portion 12. The plurality of vias 56 connects the second ground pattern 54 and the third ground pattern 55. The via 56 extends in the vertical direction and is disposed in such a way as to surround the periphery of the side face of the hollow portion 12. The installation interval of the vias 56 is less than a length of a half wavelength of a high frequency signal passing through the first strip line pattern 51 and the second strip line pattern 52.

Therefore, when the magnet 13 moves upward by the attractive force generated between the magnet 13 and the coil 16, the distance between the magnet 13 and the first strip line pattern 51 and the second strip line pattern 52 becomes long. Thus, the capacitance between them decreases. On the other hand, when the magnet 13 moves downward, the distance between the magnet 13 and the first strip line pattern 51 and the second strip line pattern 52 is shortened. Thus, the capacitance between them increases.

Therefore, the multilayer substrate according to the seventh embodiment can operate as a variable capacitance capacitor by having the above-described configuration.

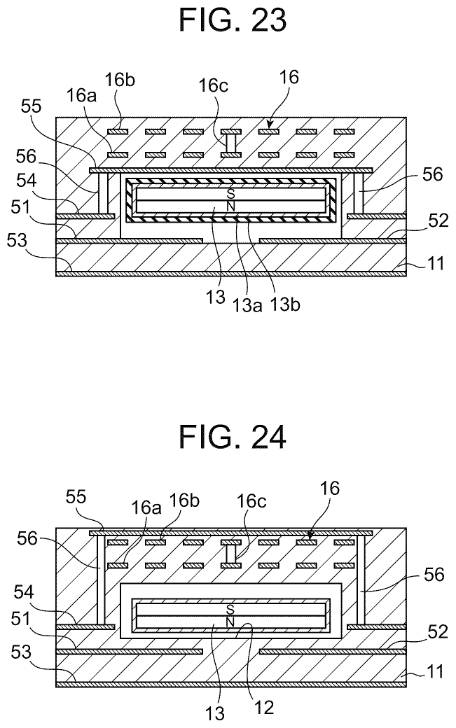

Next, a modification of the multilayer substrate according to the seventh embodiment will be described with reference to FIGS. 23 and 24.

FIG. 23 is a longitudinal cross-sectional view of Modification 1 of the multilayer substrate according to the seventh embodiment. As illustrated in FIG. 23, in Modification 1 of the multilayer substrate according to the seventh embodiment, the first strip line pattern 51 and the second strip line pattern 52 are exposed on a bottom surface of the hollow portion 12, and the magnet 13 is covered with an insulating film 13b.

FIG. 24 is a longitudinal cross-sectional view of Modification 2 of the multilayer substrate according to the seventh embodiment. As illustrated in FIG. 24, the third ground pattern 55 is disposed above the coil 16. Thus, the plurality of vias 56 is arranged in such a way as to surround the periphery of the coil 16 in addition to the hollow portion 12.

Note that the multilayer substrate according to the seventh embodiment may include a yoke 31 instead of the magnet 13.

### Eighth Embodiment

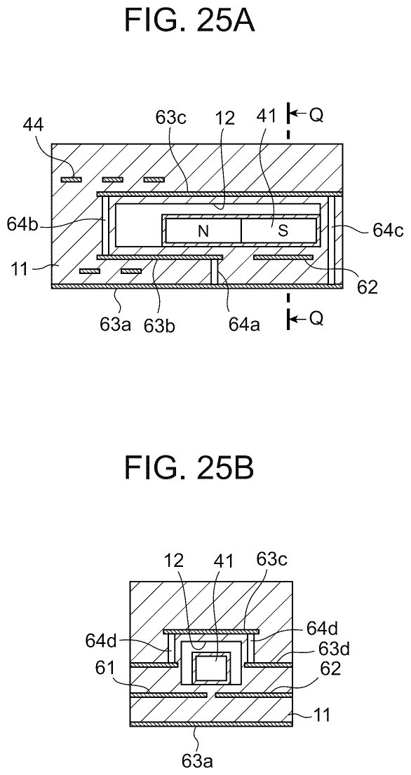

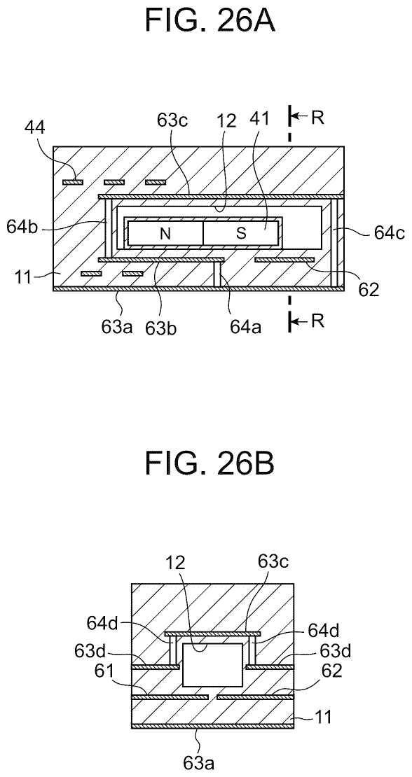

A multilayer substrate according to an eighth embodiment will be described with reference to FIGS. 25A and 25B and FIGS. 26A and 26B. FIGS. 25A and 25B are cross-sectional views of the multilayer substrate according to the eighth embodiment when a magnet 41 moves in a hollow portion 12 to a right side. FIGS. 26A and 26B are cross-sectional views of the multilayer substrate according to the eighth embodiment when the magnet 41 moves to a left side in the hollow portion 12.

As illustrated in FIGS. 25A and 25B and FIGS. 26A and 26B, the multilayer substrate according to the eighth embodiment includes a substrate body 11, a hollow portion 12, a magnet 41, a coil 44, a first strip line pattern 61, a second strip line pattern 62, a plurality of ground patterns 63a to 63d, and a plurality of vias 64a to 64d.

The first strip line pattern 61 and the second strip line pattern 62 are arranged at a lower right of the hollow portion 12. They are arranged side by side in a direction orthogonal to the moving direction of the magnet 41. One ends of the first strip line pattern 61 and the second strip line pattern 62 facing each other are located immediately below the hollow portion 12. Further, the hollow portion 12, the first strip line pattern 61, and the second strip line pattern 62 are surrounded by the plurality of ground patterns 63a to 63d and the plurality of vias 64a to 64d.

Therefore, as illustrated in FIGS. 25A and 25B, the area of the magnet 41 overlapping the first strip line pattern 61 and the second strip line pattern 62 increases as the magnet 41 moves toward the right side in the hollow portion 12. Thus, in the multilayer substrate, the capacitance increases as the area in which the magnet 41 overlaps the first strip line pattern 61 and the second strip line pattern 62 increases.

On the other hand, as illustrated in FIGS. 26A and 26B, the area of the magnet 41 overlapping the first strip line pattern 61 and the second strip line pattern 62 decreases as the magnet 41 moves toward the left side in the hollow portion 12. Thus, in the multilayer substrate, the capacitance decreases as the area in which the magnet 41 overlaps the first strip line pattern 61 and the second strip line pattern 62 decreases.

Therefore, the multilayer substrate according to the eighth embodiment can operate as a variable capacitance capacitor by having the above-described configuration.

### Ninth Embodiment

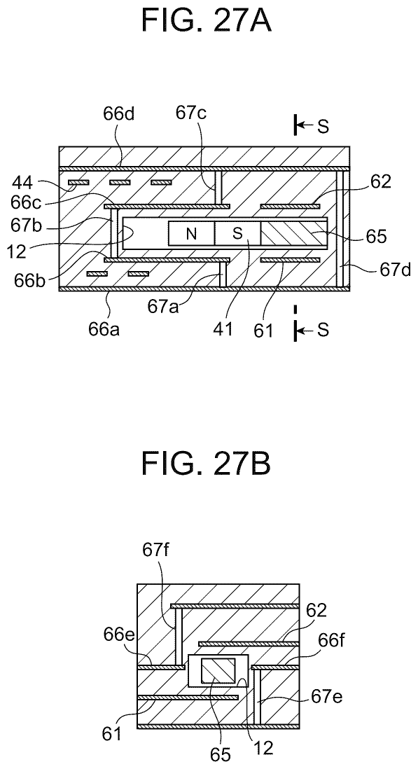

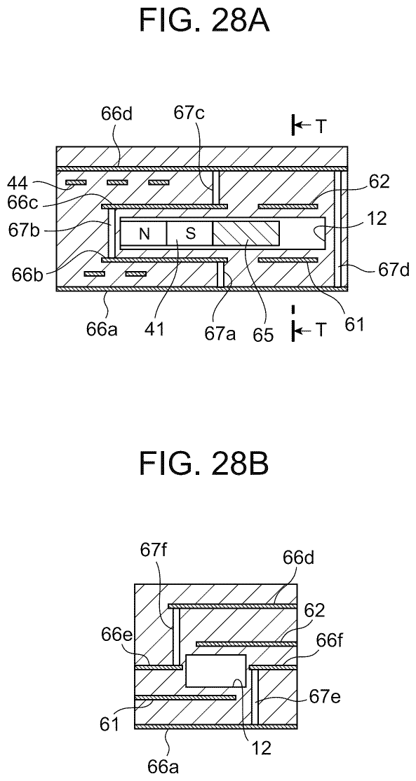

A multilayer substrate according to a ninth embodiment will be described with reference to FIGS. 27A and 27B and FIGS. 28A and 28B. FIGS. 27A and 27B are cross-sectional views of the multilayer substrate according to the ninth embodiment when a magnet 41 moves in a hollow portion 12 to a right side. FIGS. 28A and 28B are cross-sectional views of the multilayer substrate according to the ninth embodiment when the magnet 41 moves to a left side in the hollow portion 12.

As illustrated in FIGS. 27A and 27B and FIGS. 28A and 28B, the multilayer substrate according to the ninth embodiment includes a substrate body 11, a hollow portion 12, a magnet 41, a coil 44, a first strip line pattern 61, a second strip line pattern 62, a dielectric 65, a plurality of ground patterns 66a to 66f, and a plurality of vias 67a to 67f.

The dielectric 65 is provided on the right side of the magnet 41. The first strip line pattern 61 is disposed at a lower right of the hollow portion 12. The second strip line pattern 62 is arranged at an upper right of the hollow portion 12. Further, the hollow portion 12, the first strip line pattern 61, and the second strip line pattern 62 are surrounded by the plurality of ground patterns 66a to 66f and the plurality of vias 67a to 67f.

Therefore, as illustrated in FIGS. 27A and 27B, the area of the dielectric 65 overlapping the first strip line pattern 61 and the second strip line pattern 62 increases as the magnet 41 moves toward the right side in the hollow portion 12. Thus, in the multilayer substrate, the capacitance increases as the area in which the dielectric 65 overlaps the first strip line pattern 61 and the second strip line pattern 62 increases.

On the other hand, as illustrated in FIGS. 28A and 28B, the area of the dielectric 65 overlapping the first strip line pattern 61 and the second strip line pattern 62 decreases as the magnet 41 moves toward the left side in the hollow portion 12. Thus, in the multilayer substrate, the capacitance decreases as the area in which the dielectric 65 overlaps the first strip line pattern 61 and the second strip line pattern 62 decreases.

Therefore, the multilayer substrate according to the ninth embodiment can operate as a variable capacitance capacitor by having the above-described configuration.

### Tenth Embodiment

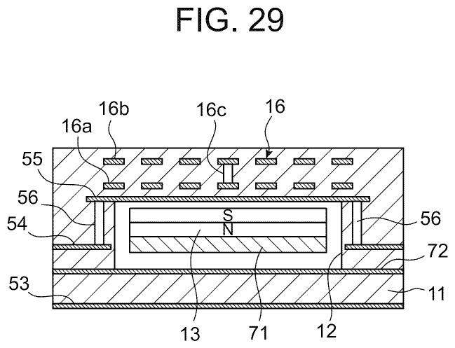

A multilayer substrate according to a tenth embodiment will be described with reference to FIG. 29. FIG. 29 is a longitudinal cross-sectional view of the multilayer substrate according to the tenth embodiment.

As illustrated in FIG. 29, the multilayer substrate according to the tenth embodiment includes a dielectric 71 and a strip line pattern 72 instead of the first strip line pattern 51 and the second strip line pattern 52 of the multilayer substrate according to the seventh embodiment illustrated in FIG. 22. The dielectric 71 is provided on a lower surface of a magnet 13. The strip line pattern 72 is provided in such a way as to be exposed on a bottom surface of the hollow portion 12.

Therefore, when the magnet 13 moves upward by attractive force generated between the magnet 13 and the coil 16, the distance between the dielectric 71 provided in the magnet 13 and the strip line pattern 72 becomes long. Thus, the effective dielectric constant of the strip line pattern 72 decreases, and thus the electrical length decreases. On the other hand, when the magnet 13 moves downward by repulsive force generated between the magnet 13 and the coil 16, the distance between the dielectric 71 provided in the magnet 13 and the strip line pattern 72 becomes short. Thus, the effective dielectric constant of the strip line pattern 72 increases, and thus the electrical length increases.

Therefore, the multilayer substrate according to the tenth embodiment can operate as a variable phase shifter by having the above-described configuration.

### Eleventh Embodiment

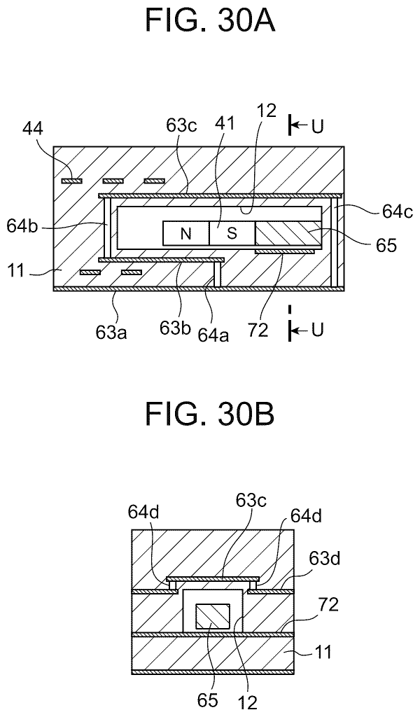

A multilayer substrate according to an eleventh embodiment will be described with reference to FIGS. 30A and 30B. FIGS. 30A and 30B are cross-sectional views illustrating a configuration of the multilayer substrate according to the eleventh embodiment.

As illustrated in FIGS. 30A and 30B, the multilayer substrate according to the eleventh embodiment includes a strip line pattern 72 instead of the first strip line pattern 61 and the second strip line pattern 62 of the multilayer substrate according to the ninth embodiment illustrated in FIGS. 27A and 27B and FIGS. 28A and 28B. The strip line pattern 72 is disposed in such a way as to form a right bottom surface of the hollow portion 12.

Therefore, the area of the dielectric 65 overlapping with the strip line pattern 72 increases as the magnet 41 moves toward a right side in the hollow portion 12. Thus, in the multilayer substrate, the effective dielectric constant of the strip line pattern 72 can be increased as the area in which the dielectric 65 and the strip line pattern 72 overlap each other is increased. Accordingly, the multilayer substrate can have a long electrical length.

On the other hand, the area of the dielectric 65 overlapping the strip line pattern 72 decreases as the magnet 41 moves toward a left side in the hollow portion 12. Thus, in the multilayer substrate, the effective dielectric constant of the strip line pattern 72 can be reduced as the area in which the dielectric 65 and the strip line pattern 72 overlap each other is reduced. Accordingly, the electrical length of the multilayer substrate can be shortened.

Therefore, the multilayer substrate according to the eleventh embodiment can operate as a variable phase shifter by having the above-described configuration.

### Twelfth Embodiment

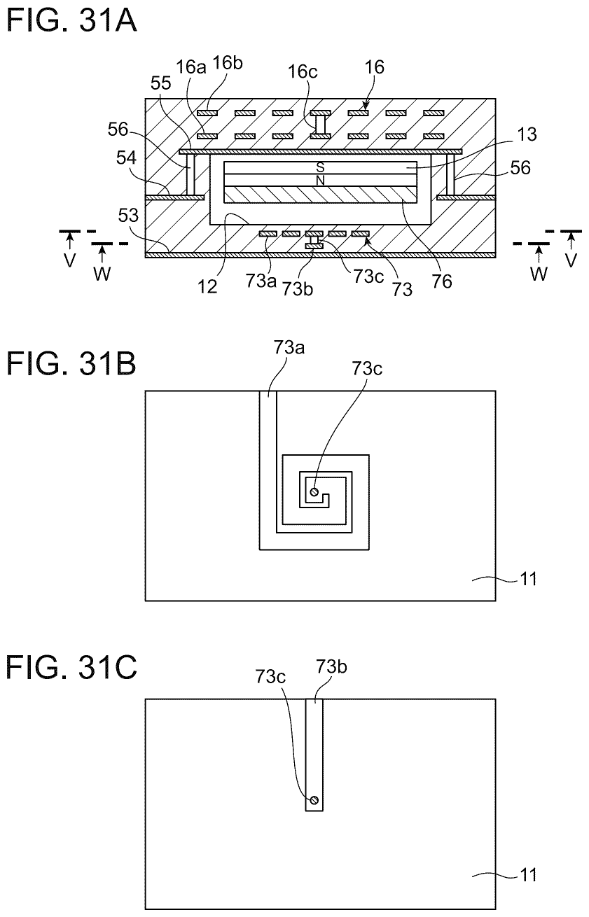

A multilayer substrate according to a twelfth embodiment will be described with reference to FIGS. 31A to 31C to FIG. 33.

FIGS. 31A to 31C are cross-sectional views illustrating a configuration of the multilayer substrate according to the twelfth embodiment. As illustrated in FIGS. 31A to 31C, the multilayer substrate according to the twelfth embodiment includes a soft magnetic body 76 and a first signal coil 73 instead of the dielectric 71 and the strip line pattern 72 of the multilayer substrate according to the tenth embodiment illustrated in FIG. 29.

The soft magnetic body 76 is provided on a lower surface of a magnet 13. The soft magnetic body 76 has a role of concentrating a magnetic field. The first signal coil 73 is provided below a hollow portion 12 in a substrate body 11. The inductance of the first signal coil 73 is variable. The first signal coil 73 includes a coil conductor pattern 73a, an extended conductor pattern 73b, and a via 73c.

Therefore, when the magnet 13 moves upward by attractive force generated between the magnet 13 and the coil 16, the distance between the soft magnetic body 76 provided in the magnet 13 and the first signal coil 73 becomes long. Thus, the inductance of the first signal coil 73 decreases. On the other hand, when the magnet 13 moves downward by repulsive force generated between the magnet 13 and the coil 16, the distance between the soft magnetic body 76 provided in the magnet 13 and the first signal coil 73 becomes short. Thus, the inductance of the first signal coil 73 increases.

Therefore, the multilayer substrate according to the twelfth embodiment can operate as a variable inductance by having the above-described configuration.

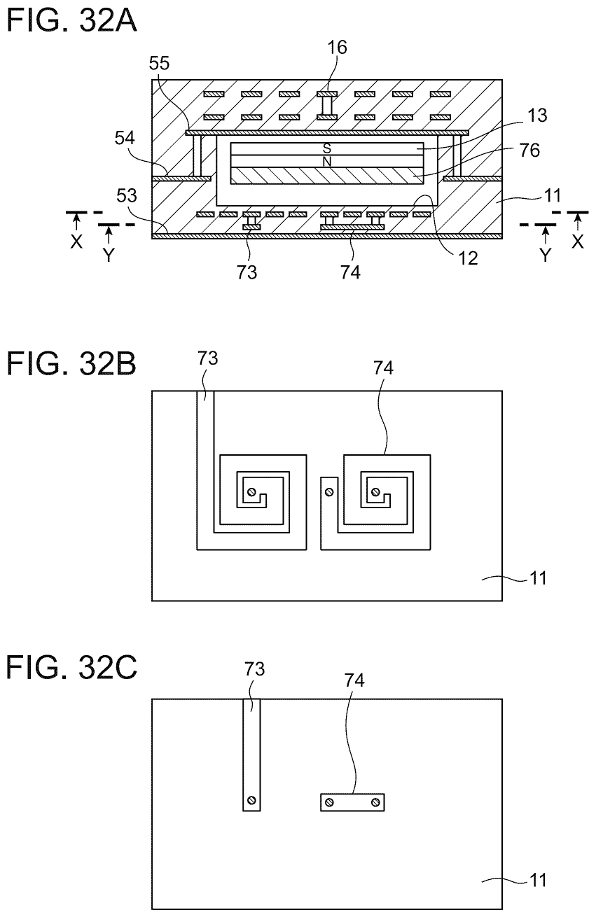

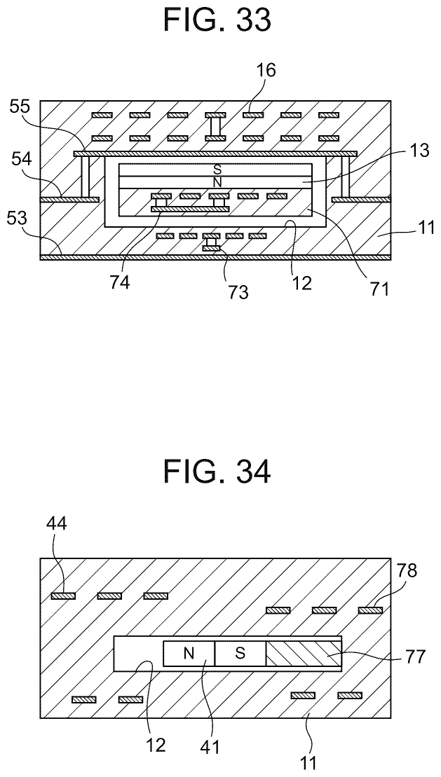

Hereinafter, a modification of the multilayer substrate according to the twelfth embodiment will be described with reference to FIGS. 32A to 32C and FIG. 33.

FIGS. 32A to 32C are cross-sectional views illustrating a configuration of Modification 1 of the multilayer substrate according to the twelfth embodiment. As illustrated in FIGS. 32A to 32C, the multilayer substrate according to the twelfth embodiment includes a first signal coil 73 and a second signal coil 74 below the hollow portion 12 in the substrate body 11. The second signal coil 74 includes a coil conductor pattern 74a, an extended conductor pattern 74b, and a via 74c.

Therefore, when the magnet 13 moves upward by the attractive force generated between the magnet 13 and the coil 16, the distance between the soft magnetic body 76 provided in the magnet 13 and the first signal coil 73 and the second signal coil 74 becomes long. Thus, the coupling coefficient between the first signal coil 73 and the second signal coil 74 decreases. As a result, the inductances of the first signal coil 73 and the second signal coil 74 decrease.

On the other hand, when the magnet 13 moves downward by the repulsive force generated between the magnet 13 and the coil 16, the distance between the soft magnetic body 76 provided in the magnet 13 and the first signal coil 73 and the second signal coil 74 becomes short. Thus, the coupling coefficient between the first signal coil 73 and the second signal coil 74 increases. As a result, the inductances of the first signal coil 73 and the second signal coil 74 increase.

FIG. 33 is a longitudinal cross-sectional view of Modification 2 of the multilayer substrate according to the twelfth embodiment. As illustrated in FIG. 33, the multilayer substrate according to the twelfth embodiment includes a second substrate 75 instead of the soft magnetic body 76. The first signal coil 73 is provided below the hollow portion 12 in the substrate body 11. The second signal coil 74 is provided on the second substrate 75.

Therefore, when the magnet 13 moves upward by the attractive force generated between the magnet 13 and the coil 16, the distance between the second signal coil 74 provided in the magnet 13 and the first signal coil 73 becomes long. Thus, the coupling coefficient between the first signal coil 73 and the second signal coil 74 decreases. As a result, the inductances of the first signal coil 73 and the second signal coil 74 decrease.

On the other hand, when the magnet 13 moves downward by the repulsive force generated between the magnet 13 and the coil 16, the distance between the second signal coil 74 provided in the magnet 13 and the first signal coil 73 becomes short.

Thus, the coupling coefficient between the first signal coil 73 and the second signal coil 74 increases. As a result, the inductances of the first signal coil 73 and the second signal coil 74 increase.

### Thirteenth Embodiment

A multilayer substrate according to a thirteenth embodiment will be described with reference to FIG. 34. FIG. 34 is a longitudinal cross-sectional view of the multilayer substrate according to the thirteenth embodiment.

As illustrated in FIG. 34, the multilayer substrate according to the thirteenth embodiment includes a substrate body 11, a hollow portion 12, a magnet 41, a coil 44, a soft magnetic body 77, and a signal coil 78. The soft magnetic body 77 is provided on a right side of the magnet 41. The coil 44 is disposed on a left side of the hollow portion 12. The signal coil 78 is disposed on a right side of the hollow portion 12.

Therefore, the length of the soft magnetic body 77 overlapping with the signal coil 78 becomes longer as the magnet 41 moves toward the right side in the hollow portion 12. Thus, the inductance of the signal coil 78 increases. On the other hand, the length of the soft magnetic body 77 overlapping the signal coil 78 decreases as the magnet 41 moves toward the left side in the hollow portion 12. Thus, the inductance of the signal coil 78 decreases.

Therefore, the multilayer substrate according to the thirteenth embodiment can operate as a variable inductance by having the above-described configuration.

### Fourteenth Embodiment

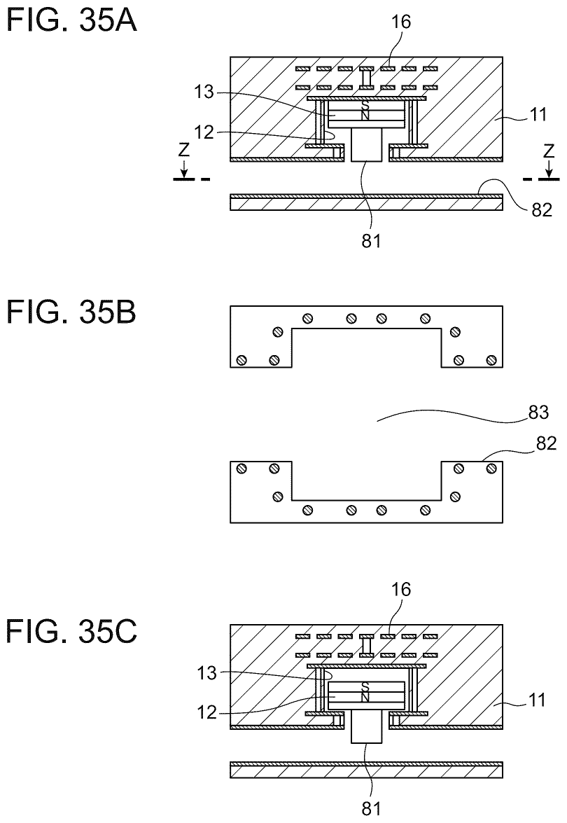

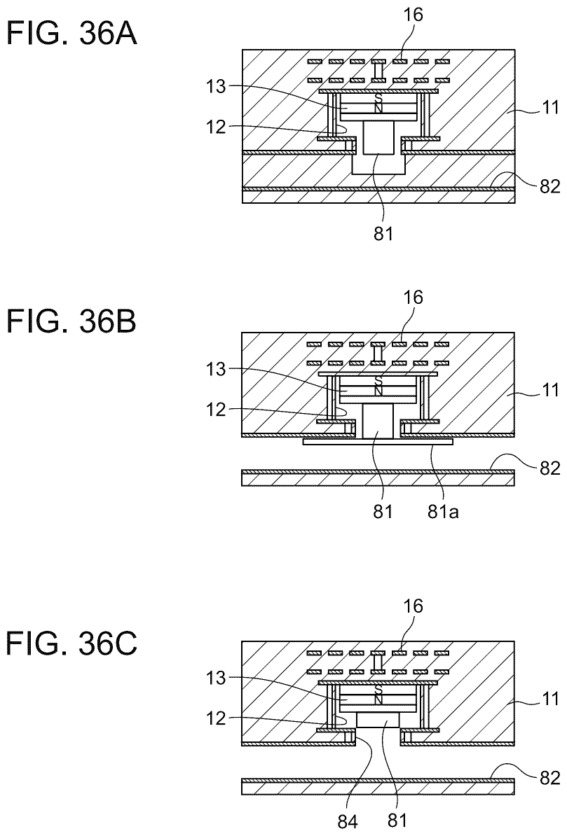

A multilayer substrate according to a fourteenth embodiment will be described with reference to FIGS. 35A to 35C and FIGS. 36A to 36C.

FIGS. 35A to 35C are cross-sectional views illustrating a configuration of the multilayer substrate according to the fourteenth embodiment. As illustrated in FIGS. 35A to 35C, the multilayer substrate according to the fourteenth embodiment includes a protrusion 81, a waveguide 82, and a cavity resonator 83.

The protrusion 81 is provided on a lower surface of a magnet 13. The protrusion 81 is formed in such a way as to protrude downward from the lower surface of the magnet 13. The protrusion 81 is formed of, for example, a conductive material.

The waveguide 82 and the cavity resonator 83 are provided below the hollow portion 12. The waveguide 82 and the cavity resonator 83 include a plurality of conductor patterns and a plurality of vias. The cavity resonator 83 is provided in a middle portion of the waveguide 82 and is located immediately below the hollow portion 12. A communication hole through which the protrusion 81 can be inserted is formed in a lower portion of the hollow portion 12. The communication hole communicates between the hollow portion 12 and the cavity resonator 83. Note that the length of each side of the hollow portion 12 is shorter than the length of ½ wavelength of the high frequency signal transmitted through the waveguide 82.

Therefore, when the magnet 13 moves up and down, the protrusion 81 provided in the magnet 13 is inserted into and pulled out of the cavity resonator 83. Thus, when the protrusion 81 formed of the conductive material is inserted into and pulled out of the cavity resonator 83, a high-frequency electromagnetic field distribution inside the cavity resonator 83 changes.

That is, since the protrusion 81 serving as a conductor is inserted into the electric field of the cavity resonator 83, the electric field hardly exists. At this time, the cavity resonator 83 can be handled in the same manner as being expanded by the insertion length of the protrusion 81. Thus, the resonance frequency of the cavity resonator 83 decreases. Therefore, the resonance frequency of the cavity resonator 83 can be controlled by adjusting the insertion length of the protrusion 81, and the cavity resonator 83 serves as a variable filter for a high frequency signal transmitted through the waveguide 82.

Therefore, the multilayer substrate according to the fourteenth embodiment can change the characteristics of the high frequency signal passing through the cavity resonator 83. Note that the protrusion 81 may be a dielectric or a magnetic body. In a case where the protrusion 81 is a magnetic body, the protrusion 81 is inserted into and pulled out of a portion having a strong magnetic field inside the cavity resonator 83.

Next, a modification of the multilayer substrate according to the fourteenth embodiment will be described with reference to FIGS. 36A to 36C. FIGS. 36A to 36C are cross-sectional views illustrating the modification of the multilayer substrate according to the fourteenth embodiment.

As illustrated in FIG. 36A, the inside of the waveguide 82 and the cavity resonator 83 may be filled with a dielectric material except for the movable range of the protrusion 81. As illustrated in FIG. 36B, the protrusion 81 may have a large diameter portion 81a. The large diameter portion 81a is formed in a flat plate shape and has an area larger than an open cross-sectional area of the communication hole. The large diameter portion 81a is disposed outside the communication hole, that is, inside the cavity resonator 83. As illustrated in FIG. 36C, in the multilayer substrate, an electrical length of a stub formed in the cavity resonator 83 may be changed instead of inserting and removing the protrusion 81 into and out of the cavity resonator 83.

### Fifteenth Embodiment

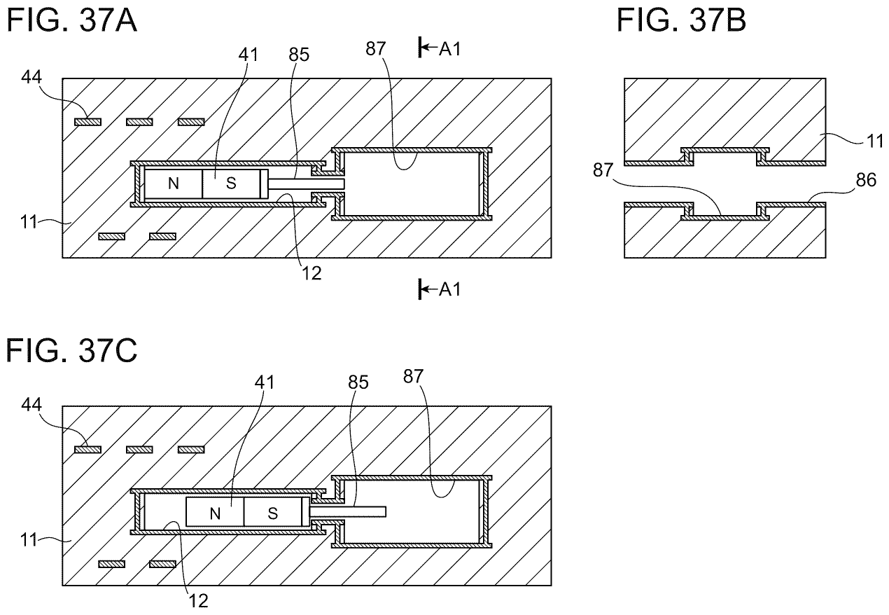

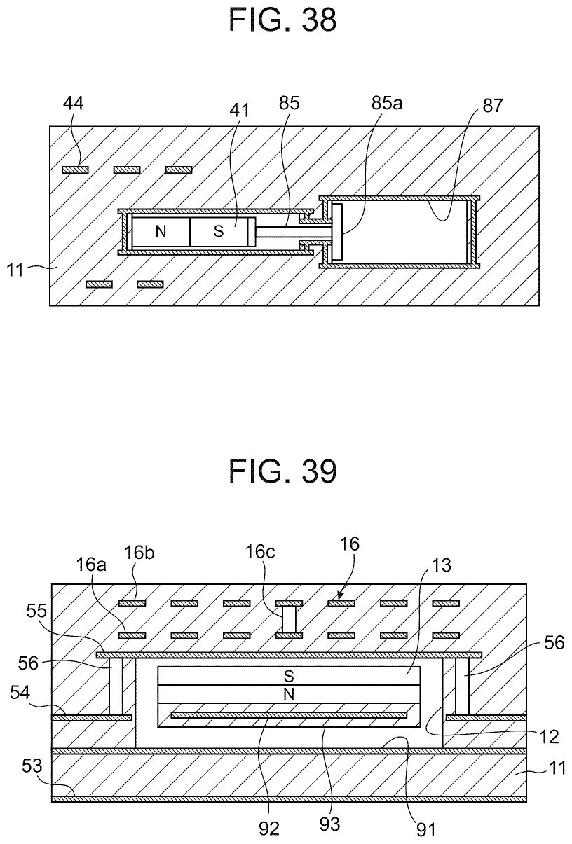

A multilayer substrate according to a fifteenth embodiment will be described with reference to FIGS. 37A to 37C and FIG. 38.

FIGS. 37A to 37C are cross-sectional views illustrating a configuration of the multilayer substrate according to the fifteenth embodiment. As illustrated in FIGS. 37A to 37C, the multilayer substrate according to the fifteenth embodiment includes a protrusion 85, a waveguide 86, and a cavity resonator 87.

The protrusion 85 is provided on a right side face of a magnet 13. The protrusion 85 is formed in such a way as to protrude outward from the right side face of the magnet 13. The protrusion 85 is formed of, for example, a conductive material.

A waveguide 86 and a cavity resonator 87 are provided on a right side of the hollow portion 12. The waveguide 86 and the cavity resonator 87 include a plurality of conductor patterns and a plurality of vias. The cavity resonator 87 is provided in a middle portion of the waveguide 86 and is located immediately beside the hollow portion 12. A communication hole through which the protrusion 85 can be inserted is formed in a side portion of the hollow portion 12. The communication hole communicates between the hollow portion 12 and the cavity resonator 87.

Therefore, when the magnet 13 moves left and right, the protrusion 85 provided on the magnet 13 is inserted into and pulled out of the cavity resonator 87. Thus, when the protrusion 85 formed of the conductive material is inserted into and pulled out of the cavity resonator 87, a high-frequency electromagnetic field distribution inside the cavity resonator 87 changes.

Therefore, the multilayer substrate according to the fifteenth embodiment can change the characteristics of the high frequency signal passing through the cavity resonator 87.

Note that the protrusion 85 may be a dielectric or a magnetic body. In a case where the protrusion 85 is a magnetic body, the protrusion 81 is inserted into and pulled out of a portion having a strong magnetic field inside the cavity resonator 83. In addition, the inside of the waveguide 86 and the cavity resonator 87 may be filled with a dielectric material except for the movable range of the protrusion 85. Further, in the multilayer substrate, the electrical length of the stub formed in the cavity resonator 87 may be changed instead of inserting and pulling the protrusion 85 into and out of the cavity resonator 87.

Next, a modification of the multilayer substrate according to the fifteenth embodiment will be described with reference to FIG. 38. FIG. 38 is a longitudinal cross-sectional view of Modification 1 of the multilayer substrate according to the fifteenth embodiment.

As illustrated in FIG. 38, the protrusion 85 may have a large diameter portion 85a. The large diameter portion 85a is formed in a flat plate shape and has an area larger than an open cross-sectional area of the communication hole. The large diameter portion 85a is disposed outside the communication hole, that is, inside the cavity resonator 87.

### Sixteenth Embodiment

A multilayer substrate according to a sixteenth embodiment will be described with reference to FIG. 39. FIG. 39 is a longitudinal cross-sectional view of the multilayer substrate according to the sixteenth embodiment.

As illustrated in FIG. 39, the multilayer substrate according to the sixteenth embodiment includes a first high frequency circuit pattern 91, a second high frequency circuit pattern 92, and a second substrate 93. The first high frequency circuit pattern 91 is provided below a hollow portion 12. The first high frequency circuit pattern 91 is disposed in such a way as to form a bottom surface of the hollow portion 12. The second substrate 93 is provided on a lower surface of a magnet 13. The second substrate 93 is provided with the second high frequency circuit pattern 92. Note that the second high frequency circuit pattern 92 is a circuit having an electrical length of ¼ wavelength of a frequency of a high frequency signal passing through the first high frequency circuit pattern 91.

Therefore, when the magnet 13 moves up and down, the distance between the first high frequency circuit pattern 91 and the second high frequency circuit pattern 92 changes, and the coupling coefficient thereof changes. As a result, in the multilayer substrate according to the sixteenth embodiment, a high frequency signal characteristic of the first high frequency circuit pattern 91 is changed according to the distance to the second high frequency circuit pattern 92, whereby a high frequency circuit having a variable function such as a variable resonator, a variable filter, and a variable attenuator can be formed.

### Seventeenth Embodiment

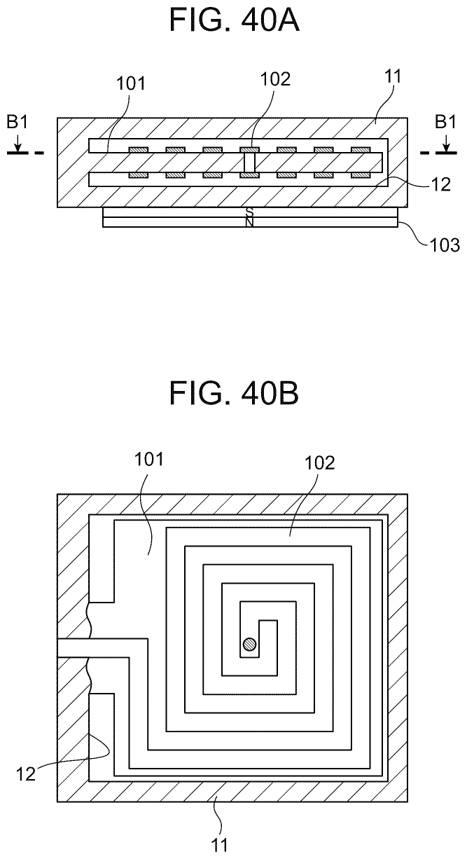

A multilayer substrate according to a seventeenth embodiment will be described with reference to FIGS. 40A and 40B. FIGS. 40A and 40B are cross-sectional views illustrating a configuration of the multilayer substrate according to the seventeenth embodiment.

As illustrated in FIGS. 40A and 40B, the multilayer substrate according to the seventeenth embodiment includes a substrate body 11, a hollow portion 12, a cantilever portion 101, a coil 102, and a magnet 103. The cantilever portion 101 serving as a movable unit is cantilevered on a side face of the hollow portion 12. A gap is formed between the cantilever portion 101 and the top surface and the bottom surface of the hollow portion 12. The coil 102 is provided in the cantilever portion 101. The magnet 103 is provided on a lower surface of the substrate body 11.

Therefore, when a current flows through the coil 102, attractive force or repulsive force is generated between the coil 102 and the magnet 103 by an interaction between a magnetic field generated in the coil 102 and a magnetic field of the magnet 103. Thus, the cantilever portion 101 is bent in the vertical direction.

Note that the installation position of the coil 102 and the installation position of the magnet 103 may be reversed. In addition, in the multilayer substrate according to the seventeenth embodiment, a yoke of a soft magnetic body may be used instead of the magnet 103.

### Eighteenth Embodiment

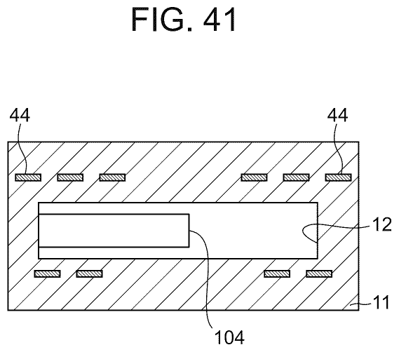

A multilayer substrate according to an eighteenth embodiment will be described with reference to FIG. 41. FIG. 41 is a cross-sectional view of the multilayer substrate according to the eighteenth embodiment.

As illustrated in FIG. 41, the multilayer substrate according to the eighteenth embodiment includes a conductor 104 instead of the yoke 31 of the multilayer substrate according to the sixth embodiment illustrated in FIG. 21.

Therefore, in a state where the conductor 104 is on the left side of the hollow portion 12, when a current flows to the coil 44 on the left side for a short time, an eddy current is generated inside the conductor 104 by an induction magnetic field. Then, when a current flows through the coil 44 on the right side in such a manner as to generate a magnetic field in a direction opposite to the magnetic field due to the eddy current inside the conductor 104 while the eddy current is generated inside the conductor 104, the conductor 104 moves toward the right side in the hollow portion 12 due to the interaction between the magnetic field in the coil 44 on the right side and the eddy current inside the conductor 104. Note that, when the conductor 104 is moved from the right side to the left side of the hollow portion 12, it is only necessary to perform the operation opposite to the above-described operation.

Note that, in the present disclosure, free combinations of the embodiments, modifications of any components of the embodiments, or omissions of any components in the embodiments are possible within the scope of the disclosure.

### Industrial Applicability

A multilayer substrate according to the present disclosure allows a movable unit to move in a hollow portion by providing a coil around the hollow portion, and is suitable for use as a multilayer substrate or the like.

### REFERENCE SIGNS LIST

11: Substrate body, 12: Hollow portion, 13: Magnet, 13a: Conductor plating, 13b: Insulating film, 14: First switch conductor pattern, 15: Second switch conductor pattern, 16: Coil, 16a: Lower layer coil conductor pattern, 16b: Upper layer coil conductor pattern, 16c: Via, 17: coil, 17a: Coil conductor pattern, 17b: Extended conductor pattern, 17c: Via, 18 and 19: coil, 20: Third switch conductor pattern, 21: Fourth switch conductor pattern, 22: Upper yoke, 23: Lower yoke, 23a: Adjustment hole, 24: Upper yoke pattern, 25: Lower yoke pattern, 26: Coil, 26a: Lower layer coil conductor pattern, 26b: Middle layer coil conductor pattern, 26c: Upper layer coil conductor pattern, 26d and 26e: Via, 27: Coil, 27a: Lower layer coil conductor pattern, 27b: Middle layer coil conductor pattern, 27c: Upper layer coil conductor pattern, 31: Yoke, 31a: Conductor plating, 32: Upper magnet, 33: Lower magnet, 34: Coil, 41: Magnet, 41a: Conductor plating, 42: First switch conductor pattern, 43: Second switch conductor pattern, 44: Coil, 44a: Coil conductor pattern, 44b: Via, 45: Magnetic body, 51: First strip line pattern, 52: Second strip line pattern, 53: First ground pattern, 54: Second ground pattern, 55: Third ground pattern, 56: via, 61: First strip line pattern, 62: Second strip line pattern, 63a to 63d: Ground pattern, 64a to 64d: Via, 65: Dielectric, 66a to 66f: Ground pattern, 67a to 67f: Via, 71: dielectric, 72: Strip line pattern, 73: First signal coil, 73a: Coil conductor pattern, 73b: Extended conductor pattern, 73c: Via, 74: Second signal coil, 74a: Coil conductor pattern, 74b: Extended conductor pattern, 74c: Via, 75: Second substrate, 76 and 77: Soft magnetic body, 78: Signal coil, 81: Protrusion, 81a: Large diameter portion, 82: Waveguide, 83: Cavity resonator, 84: Stub, 85: Protrusion, 85a: Large diameter portion, 86: Waveguide, 87: Cavity resonator, 91: First high frequency circuit pattern, 92: Second high frequency circuit pattern, 93: Second substrate, 101: Cantilever portion, 102: Coil, 103: Magnet, 104: Conductor

What is claimed is:

1. A multilayer substrate comprising:
a substrate body formed of resin or ceramic;
a hollow portion provided inside the substrate body;
a movable body provided inside the hollow portion and formed of a conductor or a magnetic body;
a coil provided around the hollow portion in the substrate body;
a protrusion provided on a lower surface of the movable body and formed of a conductive material;
a waveguide provided on the substrate body; and
a cavity resonator provided in a middle portion of the waveguide and into and out of which the protrusion is inserted and pulled.

2. A multilayer substrate comprising:
a substrate body formed of resin or ceramic;
a hollow portion provided inside the substrate body;
a movable body provided inside the hollow portion and formed of a conductor or a magnetic body;
a pair of switch conductor patterns forming a bottom surface of the hollow portion and in contact with the movable body;
a coil provided in such a way as to surround a top surface and a bottom surface of the hollow portion in the substrate body; and
a strip line pattern provided on at least one of an upper side or a lower side of the hollow portion in the substrate body.

3. The multilayer substrate according to claim 2, comprising:
a magnetic body provided inside the coil in the substrate body.

4. The multilayer substrate according to claim 2, comprising:
a dielectric provided on a side face of the movable body.

5. The multilayer substrate according to claim 2, comprising:
a signal coil provided in such a way as to surround a top surface and a bottom surface of the hollow portion in the substrate body.

6. A multilayer substrate comprising:
a substrate body formed of resin or ceramic;
a hollow portion provided inside the substrate body;
a movable body provided inside the hollow portion and formed of a conductor or a magnetic body;
a pair of switch conductor patterns forming a bottom surface of the hollow portion and in contact with the movable body;
a coil provided in such a way as to surround a top surface and a bottom surface of the hollow portion in the substrate body;
a protrusion provided on a side face of the movable body and formed of a conductive material;
a waveguide provided on the substrate body; and
a cavity resonator provided in a middle portion of the waveguide and into and out of which the protrusion is inserted and pulled.
